(19) United States
(12) Patent Application Publication
(10) Pub. No.: US 2023/0176746 A1
(43) Pub. Date: Jun. 8, 2023

(54) VALIDITY OF INFORMATION STORED IN MEMORY DEVICES

(71) Applicant: Hewlett-Packard Development Company, L.P., Spring, TX (US)

(72) Inventors: Adrian John Baldwin, Bristol (GB); Pierre Belgarric, Bristol (GB); Christopher Ian Dalton, Bristol (GB); Thalia May Laing, Bristol (GB)

(73) Assignee: Hewlett-Packard Development Company, L.P., Spring, TX (US)

(21) Appl. No.: 17/457,571

(22) Filed: Dec. 3, 2021

(51) Int. Cl. G06F 3/06; G06F 12/14

(52) U.S. Cl. CPC G06F 3/0619; G06F 3/0659; G06F 3/0679; G06F 12/1408

(57) ABSTRACT

In an example, an apparatus is described. The apparatus comprises a memory device comprising a set of logical cells. A logical cell of the set of logical cells indicates a data value by an amount of charge stored in a physical cell of the logical cell. Charge leakage between the physical cell and an adjacent physical cell of the logical cell is to occur at a rate that at least partially depends on a relative amount of charge stored in the physical cell and the adjacent physical cell. A set of data values indicated by the set of logical cells is to change over time due to the charge leakage. The set of data values indicated by the set of logical cells is representative of information that is valid over an estimated period of time, which is based on the rate of charge leakage.

### BACKGROUND

Some memory devices such as hard disk drives, optical discs and flash memory may be expected to store data for a long period of time (e.g., many years). Such memory devices may be designed in such a way to minimize data degradation over the anticipated lifetime of the memory device.

### BRIEF DESCRIPTION OF DRAWINGS

Non-limiting examples will now be described with reference to the accompanying drawings, in which:

FIG. 1 is a simplified schematic drawing of an example apparatus for storing information;

FIG. 2 is a simplified schematic drawing of an example computing system for hosting the apparatus of FIG. 1;

FIG. 3 is a simplified schematic drawing of an example apparatus for storing information;

FIG. 4 is a schematic illustration of an example apparatus for storing information;

FIG. 5 depicts a flowchart of an example method of storing information;

FIG. 6 depicts a flowchart of an example method of applying an error correction code;

FIG. 7 depicts a flowchart of an example method of defining different charge leakage rates;

FIG. 8 is a simplified schematic drawing of an example apparatus for providing an interface to a memory device;

FIG. 9 is a simplified schematic drawing of an example architecture for an apparatus;

FIG. 10 is a simplified schematic drawing of an example apparatus for providing an interface to a memory device;

FIG. 11 is a simplified schematic drawing of an example apparatus for providing an interface to a memory device;

FIG. 12 is a simplified schematic drawing of an example apparatus for providing an interface to a memory device;

FIG. 13 is a simplified schematic drawing of an example apparatus for providing an interface to a memory device;

FIG. 14 is a simplified schematic drawing of an example apparatus for providing an interface to a memory device;

FIG. 15 is a simplified schematic drawing of an example apparatus for providing an interface to a memory device;

FIG. 16 is a simplified schematic drawing of an example apparatus for providing an interface to a memory device;

FIG. 17 schematically illustrates an example machine-readable medium for facilitating provision of an interface to a memory device; and

FIG. 18 depicts a flowchart of an example method of operating an interface.

### DETAILED DESCRIPTION

Some memory devices are based on floating gate technology in which an array of physical cells each hold charge representative of a data value stored in the physical cell. An example of such a memory device is a NAND flash device, e.g., based on 2D or 3D NAND technology. In a 2D NAND flash memory device, the physical cells may be arranged side-by-side in a ‘2D’ layer. In a 3D NAND flash memory device, such layers of physical cells may be vertically stacked. Compared with a 2D NAND flash memory, a 3D NAND flash memory device may store a large amount of data due to the number of physical cells that can be accommodated within a volume.

In some examples, a set of data-storing physical cells of a 3D NAND flash memory may be connected in a cell string associated with a bit line of the memory. A set of cell strings may be represented as a block where each cell string of the block may intersect a number of word lines of the block (and where each word line connects the physical cells that have the same position along each of the cell strings). A control gate of each physical cell in the cell string may be connected to the word lines in the block. A word line may connect all physical cells in the same position in the strings, and define a page within the block.

While some memory devices may store data for a long period of time (e.g., many years) without error, some memory devices may experience degradation of data stored therein due to physical processes in the device that cause errors in the stored data. For example, certain memory devices such as 3D NAND flash memory devices may have a reliability issue where electrons migrate (or ‘leak’) between adjacent physical cells (e.g., between adjacent cells in a cell string). Put another way, the electrons may migrate between adjacent cells in a cell string that intersects neighboring word lines.

If a data-holding physical cell is adjacent to another physical cell (e.g., in a cell string) which stores a relatively high number of electrons, this reliability issue may be reduced or mitigated such that the memory device may store data for a long period of time without error. However, if the adjacent physical cell (e.g., in a cell string) stores relative few electrons, the reliability issue may become more apparent since electrons may leak from the data-holding physical cell to the adjacent physical cells due to an electric field formed between the adjacent physical cells when there is a difference between the charge stored in the adjacent physical cells (e.g., providing the adjacent physical cells are sufficiently proximal to each other to increase the likelihood of the charge leakage effect). In a 3D NAND flash memory, the charge leakage effect may occur laterally between adjacent physical cells of a cell string associated with a bit line.

There may even come a point where the charge leakage changes the bit value represented by the stored charge in the physical cell. For example, if a programmed physical cell stores a number of electrons (e.g., corresponding to a bit value of 0) and a certain number of those electrons leak to an adjacent physical cell (e.g., storing a relatively low number of electrons), the bit value may flip to 1 (i.e., cleared/erased). Therefore, the charge leakage effect may, in certain circumstances, lead to degradation of the data stored in certain types of memory devices which exhibit charge leakage when adjacent physical cells store a certain amount of charge.

Memory devices may implement various mechanisms to reduce data degradation due to this charge leakage effect.

As used herein, a ‘memory device’ may refer to any memory device which stores data where the level of stored charge in a physical cell of the memory device is indicative of a bit value (or an analog value) and where a charge leakage effect may occur between adjacent physical cells to potentially cause data degradation. An example of such a memory device is a 3D NAND flash memory.

### Validity of Information Stored in Memory Devices

While certain mechanisms may be used to reduce data degradation due to the charge leakage effect, it may be possible to exploit this charge leakage effect for various purposes as described herein, for example, improving control of access to information.

FIG. 1 is a schematic illustration of an example apparatus 100 for storing information. The apparatus 100 may be provided as a standalone device or as part of a system such as described below. In some examples, the apparatus 100 may be communicatively coupled to an interface (as discussed below) for controlling memory operations carried out in the apparatus 100.

The apparatus 100 comprises a memory device 102 such as described above. The memory device 102 comprises a set 104 of logical cells 106. Each logical cell 106 comprises at least one physical cell. Two physical cells 108a, 108b (collectively 108) are depicted in each logical cell 106. While two physical cells 108 are depicted in each logical cell 106, more physical cells 108 may be part of the same logical cell 106 such as three or more. Further, in some examples, while two logical cells 106 are depicted as being part of the set 104, many more logical cells 106 may be part of the same set 104. Further, in some examples, the set 104 of logical cells 106 may be in a dedicated namespace of the memory device 102. In some examples, this dedicated namespace may be in addition to another namespace of the memory device 102 comprising physical cells 108 which may or may not be addressable as logical cells 106.

In some types of memory devices 102, the physical cell 108a and the adjacent physical cell 108b may each be in adjacent word lines (i.e., they may share the same bit line) and subject to a lateral charge leakage effect as described above.

For the purpose of this discussion, one of the physical cells 108a may be used for indicating a data value while the other of the physical cells 108b, which is adjacent to the physical cell 108a, may be used for another purpose as described below.

A logical cell 106 of the set 104 of logical cells 106 indicates (via the physical cell 108a) a data value (such as a bit value or an analog value such as based on a measurable voltage associated with the physical cell 108a) by an amount of charge stored in the physical cell 108a. In use of the apparatus 100 (e.g., storing data over a period of time), charge leakage between the physical cell 108a and the adjacent physical cell 108b is to occur at a rate that at least partially depends on a relative amount of charge stored in the physical cell 108a and the adjacent physical cell 108b. In other similar words, the rate may at least partially depend on a difference between the amount of charge stored in the physical cell 108a and the adjacent physical cell 108b. In some cases, the rate may also depend on other factors such as the absolute amount of charge stored in the physical cell 108a and the adjacent physical cell 108b. Thus, the ‘adjacent’ physical cell 108b may encode a charge leakage rate based on the amount of charge stored in the data-holding physical cell 108a. In this case, the adjacent physical cell 108b may be referred to as a ‘degradation rate’-encoding physical cell.

Therefore, in use of the apparatus 100 (e.g., for storing data), a set of data values indicated by the set 104 of logical cells 106 is to change over time due to the charge leakage (or at least it can be expected that the set of data values may change over time). Not all data values indicated by the physical cells 108 can change. For example, in the case of 3D NAND flash memory, a programmed physical cell 108 may correspond to a bit value of 0 (forming part of a valid piece of information) and may change to an erased state corresponding to a bit value of 1 over time due to the charge leakage effect. In contrast, a physical cell 108 indicating a bit value of 0 (also forming part of the valid piece of information) may not change over time due to the charge leakage effect.

Thus, the set of data values indicated by the set 104 of logical cells 106 is representative of information that is valid over an estimated period of time. The estimated period of time is based on the rate of charge leakage. For example, at a certain time (e.g., within the estimated period of time), the set of data values may represent valid information and at another time (not within the estimated period of time), the set of data values may represent at most partially valid information. Thus, valid information may be extracted from the memory device 102 within the estimated period of time. In an example, the information may start as valid (after a memory operation is performed) and then become invalid over time due to charge leakage. In another example, the information may start as invalid (e.g., at most partially valid) and then become valid over time due to charge leakage. In a related example, the information may again become invalid due to further charge leakage.

The period of time may be ‘estimated’ because the rate of charge leakage may vary depending on various factors (such as the characteristics of the memory device 102, statistical factors and/or environmental conditions). The accuracy of any prediction of the timing of the change in data value may vary correspondingly, and hence the period of time over which the information is valid may be estimated. Therefore, the information represented by the set of data values may be valid over (e.g., within) the estimated period of time and invalid outside of (e.g., not within) the estimated period of time. In example implementation of the apparatus 100, if a user wishes to ensure that information valid over a target period of time (e.g., between a target start time and target end time), they may wish to interface with the apparatus 100 (as described in more detail below) in such a way that the estimated period of time is longer than the target period of time to increase the likelihood that the information is valid over the target period of time.

As discussed below, the estimated period of time may be such that the information is valid for: a certain amount of time after a memory write operation is performed; after a certain amount of time has elapsed after a memory write operation has been performed; within a time window that starts a certain amount of time after a memory write operation is performed and ends after the estimated period of time has elapsed; or when certain conditions are met. In other similar words, reading the set of data values at any point over (e.g., during) the estimated period of time may yield the valid information. However, reading the set of data values at any other point that is not during the estimated period of time may yield invalid information (e.g., at most partially valid information).

In some examples, the ability to vary the timing of when valid information can be accessed may be useful for certain types of information in various scenarios. Rather than a software-based approach for controlling access to valid information physical process is used to control the access in such a way that may be more difficult to comprise than the software-based approach. In other words, the charge leakage effect may be considered to be a passive process relying on the ‘natural’ process of physical cells losing charge to change the stored data such that the information is valid over the estimated period of time.

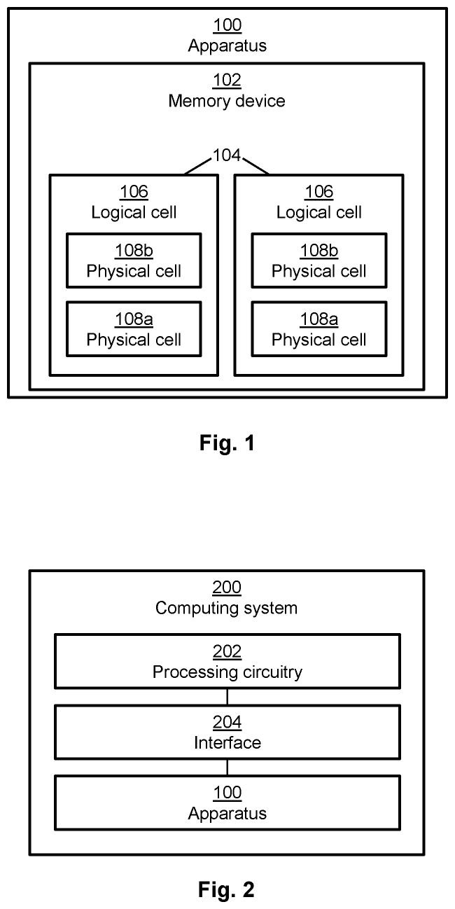

FIG. 2 is a schematic illustration of an example computing system 200 in which certain examples described herein may be implemented (e.g., the apparatus 100 or any other memory device described herein). In this example, the computing system 200 comprises (e.g., hosts) the apparatus 100. The apparatus 100 is communicatively coupled to processing circuitry 202 (e.g., a central processing unit (CPU) of a motherboard) of the computing system 200 via an interface 204 (as described below, which may be part of the apparatus 100 or separate to, but trusted by, the apparatus 100). The occurrence of the charge leakage effect may affect the data values stored in the apparatus 100 such that the information is valid over the estimated period of time and invalid or at most partially valid at other times. The computing system 200 may request that various memory operations be performed in the apparatus 100 (where such memory operations may be controlled and/or implemented by the interface 204).

In an example, the computing system 200 may request that a data write operation be implemented in the apparatus 100. In another example, the computing system 200 may request that a data read operation be implemented in the apparatus 100.

In an example, the computing system 200 may be an end-user device such as a laptop, personal computer, tablet, phone, Internet of Things (IoT) device, etc. In another example, the computing system 200 may be a computer controlled by another entity such as a manufacturer of (e.g., a component of) an end-user device, a service/repair entity, distributor, etc.

Various examples described below may also refer to example scenarios where this data access control may be implemented.

In an example scenario, an original equipment manufacturer (OEM) may store a set of data values in the apparatus 100 installed in an end-user device. In an example, upon shipping, the set of data values may not represent valid information. However, the set of data values may represent valid information over the estimated period of time after shipping, where the estimated period of time is such that a certain access condition is met. For example, the estimated period of time may refer to a certain duration of time during distribution (e.g., so that a certain entity within the distribution chain can access the valid information during the estimated period of time). Valid information may allow certain functions (e.g., of the end-user device) to be accessed by an authorized entity (who is expected to have possession of the end-user device during the estimated period of time). Use of the information may be an indication of authorized access if the information is valid or unauthorized access if the information is invalid. For example, the information accessed from the apparatus 100 may be sent to an entity for verifying access to the information, which may provide an indication of whether the end-user device is being used in an expected way.

In another example scenario, an end user may wish to store information on the apparatus 100 but define how long the information is to remain valid for (e.g., over the estimated period of time).

In another example scenario, keeping data private or available for restricted time periods may involve use of a management system for facilitating control over this data to a custodian of the data (e.g., an end user about which the data relates). However, with the increasing number of computing devices held by users such as IoT devices, there may be difficulties with implementing such management systems. For example, a medical device may be provided to an end user for home monitoring and treatment. The medical device may store data for monitoring and later upload this data to a server. However, the medical device may be returned and shipped to other patients, increasing the risk of unintentional data disclosure. By rendering any ‘information’ (i.e., data of interest such as private/confidential data and/or access data for accessing the private/confidential data) invalid outside the estimated period of time, the risk of unintentional data disclosure may be reduced.

In connection with any of the example scenarios, an entity that writes a set of data values to the apparatus 100 may have confidence that valid information is accessible over the estimated period of time and invalid or at most partially valid information is accessible outside the estimated period of time. Since the data values may change due to a physical process, rather than via a software-based approach for controlling access, the entity may have confidence that access to information may be controlled (e.g., for privacy or security reasons) and/or that there is a reduced risk of a compromise in the software-based approach which could otherwise lead to unauthorized access to valid information.

Various examples described below refer to example types of information that may be stored in valid form in the apparatus 100 over the estimated period of time in various contexts.

In an example, the information may comprise personal data that may be kept (in a valid form) for a restricted period of time (e.g., corresponding to the estimated period of time) but with an expectation that such information is to be deleted afterwards (e.g., rendered invalid or at most partially valid).

In another example, information forming at least part of a document may be released (e.g., rendered valid) after a certain amount of time has elapsed, for example, as part of a bidding process.

In another example, the information that is rendered invalid outside the estimated period of time may be part of a document where the information relates to portions of the document that are redacted except when the information is valid. This may be useful for controlling access to sensitive or secret documents and ensuring the destruction or invalidation of the sensitive/secret portions of the document.

In another example, pseudonymized data (e.g., a token) and/or encrypted data (e.g., separate to the ‘information’ referred to the above) may be rendered unreadable while the information (e.g., a cryptographic key, a token lookup table, etc.) stored in the apparatus 100 is invalid outside the estimated period of time.

In another example, the information may comprise clear text data that is readable without access to a token lookup table or cryptographic key. In other words, the information may be unencrypted or interpretable without access to other data.

In another example, the information may comprise access data (e.g., a token lookup table, cryptographic key, etc.) that is usable to provide access to content of certain data of interest where access to this data depends on whether the information (‘access data’) is valid or invalid.

In the above examples, the information that is rendered valid or invalid depending on the time of access may be the data of interest (which may be private, confidential, secret, etc.) and/or the information may be ‘access data’ to facilitate access to the data of interest (e.g., stored in another namespace of the memory device or a different memory device entirely).

Various examples described below refer to further details of how to control access to various types of information over time.

In an example referred to above, the information is at least part of a type of ‘access data’ for facilitating access to data of interest.

In an example, the ‘information’ may comprise ‘access data’ such as at least part of a cryptographic key, a token table (which may be used for looking up a corresponding text/character string associated with each token in the table) and/or a token. Such information may be used to decrypt encrypted data and/or recover pseudonymized data of interest. However, due to the charge leakage effect described above, the information used for accessing such data of interest may be valid over the estimated period of time and invalid outside the estimated period of time. The difficulty of recovering the data of interest using the degraded/invalid information may depend on the implementation. For example, it may be very challenging to recover encrypted data based on an invalid cryptographic key. In the case of a token lookup table, there may be circumstances where a partially valid token lookup table may still be used to recover pseudonymized data (e.g., for a certain amount of time). In an example, the token table may form part of information that may change over time so that the number of valid entries in the token table may change over time so that the token table may provide the valid text/character string at a certain time. In another example, a token used for providing access to data of interest may be partially valid (for example, the ‘most significant bits’ (MSBs) of a token may be valid at a certain time) such that a correct entry from the data of interest (e.g., a token table) may be returned when the token used to access the data of interest is valid (e.g., if the token validly matches an entry in the token table). An example scenario may be that there are a number of possible token table entries and when the token ‘access data’ is valid, it may match one of the entries corresponding to the data of interest.

In case of loss of control over a computing system by an entity such as an end user or other authority, the data degradation may reduce the risk of unauthorized access to the information stored in the apparatus 100 if the information becomes invalid after the estimated period of time. Data recovery could be implemented by an appropriately equipped authority (with appropriate knowledge of how to speed up accessing the data of interest) that invests CPU power to reduce the time to data recovery. However, the more the data degrades, the difficulty of recovering the data of interest (e.g., based on a crypto-analysis technique) may increase.

In some examples described in more detail below, it is proposed to make the difficulty of recovering the data of interest (e.g., the information itself or data of interest accessible using the information) a function of a parameter such as time or some other parameter like access pattern sequence. The function can be such that the ease of access increases with time, decreases with time or is within a window of time (increasing followed by decreasing). In another example, the function may further depend on a memory operation such as a read/write operation being carried out. In an example scenario, an attacker might introduce an error into the data values (e.g., of an adjacent physical cell) by performing a memory operation which might render a (random) data value unreadable for or after a certain period of time after the memory operation is performed (e.g., if the expected data degradation is prevented or otherwise adversely affected by the memory operation). Further details of such functions are provided in the examples described below.

In an example, the data of interest may be more difficult to retrieve over time. For example, the ‘information’ may initially be valid over the estimated period of time and then degrade after the estimated period of time has elapsed.

An example way to make the data of interest more difficult to retrieve over time may be to make decryption difficulty a function of time, and potentially some other parameter (e.g., a read/write sequence in a set of memory operations implemented in the device e.g., to deliberately set or modify a data degradation rate or as a consequence of an attacker introducing an error in the data values that is not correctible leading to data being unable to be recovered due to the attacker's error). In an example, making the decryption difficulty a function of time may be implemented using a cryptographic key (associated to the encrypted content of interest) that gets more difficult to recover over time (as a result of time flowing or occurrence of certain events such as a read/write sequence).

For example, this could mean that the entity accessing the content may need to choose which content of a dataset to decrypt because it may be computationally expensive to decrypt several sets of data of interest encrypted with several different keys. An example scenario may be there is a low probability that an entire encrypted dataset needs to be accessed simultaneously. There may be a plurality of cryptographic keys associated to the encrypted dataset where each cryptographic key may decrypt a certain part of the dataset but the entire dataset may not be unlockable at once if each cryptographic key (stored as ‘information’ in the apparatus 100) is valid over different periods of time.

In some examples, the data of interest may be stored (e.g., in the same namespace or a different namespace to the access data) as valid information over the estimated period of time so that if the access data is needed to convert the data of interest from an unreadable to readable form, both the access data and the data of interest may need to be valid in order for the data of interest to be accessed (e.g., to provide additional protection against data exposure if the access data is fully available).

The above examples refer to cryptographic keys but other types of ‘access data’ such as token lookup tables may be accessible over the estimated period of time.

In some examples, making the data of interest more difficult to retrieve over time may be useful in contexts where data still needs to be accessible after a certain period of time (for example, for regulatory reasons), or where access to the data of interest is expected to become more rare over time (for example, because the more recent the data of interest is, the more relevant it is likely to be) but is sensitive enough that its access represents a privileged operation (e.g., an authorized entity may have a privilege level to facilitate access to a recovery protocol such as via an error correction code as described below).

In some examples, making the data of interest less difficult to retrieve over time may be used where it could be valuable to have data of interest ‘appear’ after some time. An example scenario may be where some code is implemented in a product but is not to be accessible before a given date, for example, because it could reveal some intellectual property or some vulnerability in the case of security patching. In other words, the access data may become easier to use over time (e.g., the cryptographic key may start as unreadable (invalid) to fully readable (valid) in after a certain amount of time, after which the key is readable over the estimated period of time).

In some examples, the access data may be valid during a window of time (with a start time of ‘t_1’ and an end time of ‘t_2’) and invalid outside the window of time. For example, the access data over time making access easier after time t_1, before disappearing over a longer time t_2>t_1.

Some examples relating to the above are described below.

In some examples, the estimated period of time has a start time of when a data write operation is performed to store the information in the set 104 of logical cells 106 and an end time, after which the information becomes at least partially invalid due to at least one data value indicated by the set 104 of logical cells 106 changing due to the charge leakage.

In some examples, the estimated period of time has a start time after a data write operation is performed to store a set of data values in the set 104 of logical cells 106. In use, the stored set of data values is to change over time due to the charge leakage before the information becomes valid over the estimated period of time.

In some examples, the estimated period of time has an estimated start time after a data write operation is performed to store a set of data values in the set 104 of logical cells 106. In use, the stored set of data values is to change over time due to the charge leakage before the information becomes valid over the estimated period of time. The estimated period of time also has an estimated end time, after which the information becomes at least partially invalid due to at least one data value indicated by the set 104 of logical cells 106 changing due to further charge leakage.

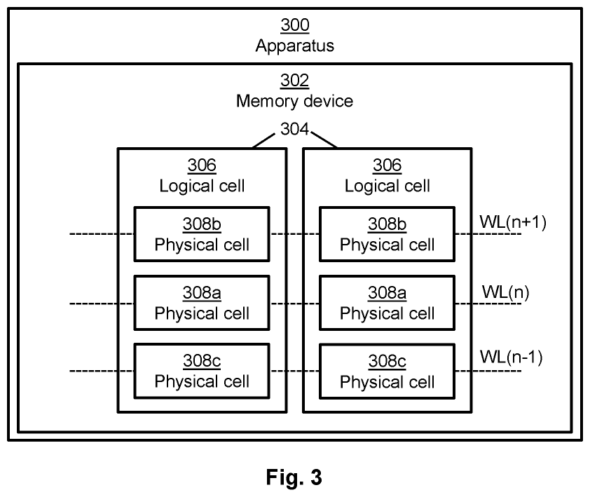

FIG. 3 is a simplified schematic drawing of an example apparatus 300 for storing information. The apparatus 300 is similar to the apparatus 100 of FIG. 1 and may be implemented in the same way as the apparatus 100 of FIG. 1. In FIG. 3, reference signs for features of the apparatus 300 that are similar or like corresponding features of the apparatus 100 are incremented by 200 compared with FIG. 1.

The apparatus 300 comprises a memory device 302, which comprises a set 304 of logical cells 306 (e.g., within a namespace of the memory device 302). Each logical cell 306 of the set 304 comprises a first physical cell 308a (e.g., a ‘data-holding’ physical cell) for storing charge indicative of the data value. Each logical cell 306 further comprises a second physical cell 308b adjacent to the first physical cell 308a. Each logical cell 306 further comprises a third physical cell 308c adjacent to the first physical cell 308a. As depicted by FIG. 3, the first physical cell 308a represents a ‘central’ cell surrounded by the adjacent physical cells 308b, 308c.

Charge stored in the second and third physical cells 308b, 308c is to control the rate of charge leakage between the first physical cell 308a and the second and third physical cells 308b, 308c. For example, charge may or may not leak between the first physical cell 308a and the second and third physical cells 308b, 308c depending on the relative amount of charge stored in each of the physical cells 308a-c.

In this example of the apparatus 300, two logical cells 306 are depicted in the set 104 although many more logical cells 306 may be provided in the set 304 (e.g., within a namespace of the memory device 302). The example of FIG. 3 also depicts that the first physical cells 308a of the two depicted logical cells 306 are in the same word line, WL(n), i.e., the n-th word line (within an array of word lines not shown). Similarly, the second physical cells 308b of the two depicted logical cells 306 are in the same word line, WL(n+1), i.e., the (n+1)-th word line (within the array of word lines). Similarly, the third physical cells 308c of the two depicted logical cells 306 are in the same word line, WL(n−1), i.e., the (n−1)-th word line (within the array of word lines). In some examples, each word line of the array may comprise a physical cell 308 from adjacent logical cells 306 in the word line. Further, in some examples, the physical cells 308 within each logical cell 306 may be part of a cell string connecting the first, second and third physical cells 308 (the cell string is not depicted but extends ‘vertically’ in FIG. 3, and connects the first, second and third physical cells 308c). In some examples, each cell string may comprise multiple logical cells 306. As discussed previously, in some memory devices 302, a lateral charge leakage effect may occur between physical cells 308 of adjacent word lines (e.g., from WL(n) to WL(n+1) and/or WL(n−1)), which may facilitate the implementation of various examples described herein.

In this example, the set 304 of logical cells 306 have three possible logical states.

In a first logical state, the charge stored by each first physical cell 308a of the set 304 of logical cells 306 is indicative of a valid data value making up part of the information. This first logical state may be referred to as a ‘cleartext’ state (i.e., the data values stored by the set 304 is made up of 0s and 1s and represents valid information). The cleartext state is to be distinguished from a deleted/erased state as described below. When referring to an individual physical cell 308, it may be ‘programmed’ (e.g., indicating a bit value of 0) or ‘clear’ (e.g., indicating a bit value of 1). The individual physical cell 308 may hold a part of valid information whether it is indicating a 0 or 1 if the set 304 of logical cells 306 are in the ‘first logical state’. Thus, the first logical state (and other logical states described below) refer to the collective state of the set 304 of logical cells 306 rather than the state of an individual physical cell 308.

In a second logical state, the charge stored by each first physical cell 308a of a first subset (e.g., at least one) of the set 304 of logical cells 306 is indicative of a valid data value making up part of the information. Further, the charge stored by each first physical cell 308a of a second subset (e.g., as least one) of the set 304 of logical cells 306 is indicative of an invalid data value such that the information is masked by the second subset, In other similar words, the first subset of the set 304 comprises physical cells 308 (of at least one logical cell 306) indicating a valid data value making up part of the information while the second subset of the set 304 comprises physical cells 308 (of at least one different logical cell 306) indicating an invalid data value such that the information is at least partially masked by the (at least one) invalid data value. In some circumstances, it may be difficult to recover data of interest based on information that has at least one invalid data value.

In a third logical state, the charge stored by each first physical cell 308a of the set 304 of logical cells 306 is such that the set 304 of logical cells 306 is erased of any information.

An example implementation of the apparatus 300 is described below in the context of an example of a flash memory such as a 3D NAND flash memory. Other types of memory devices may have different implementations while still providing the functionality of certain examples described herein. In some examples, the memory device 302 is a type of floating-gate memory.

In accordance with the example implementation, each logical cell 306 comprises three physical cells 308. These three physical cells 308 are adjacent to each other in a cell string, as described above. The first (‘central’) physical cell 308a of the logical cell 306 may indicate a bit value (or an analog value) while the degradation rate of this physical cell 308a is set by its two ‘surrounding’ physical cells 308b-c (also referred to herein as ‘timing’ physical cells 308b-c since they control the timing of when the first physical cell 308a transitions from a bit value of ‘0’ to ‘1’) of its respective logical cell 306. In some examples, the two ‘surrounding’ physical cells 308b-c cells may not be expected to explicitly hold information apart from the degradation rate (thus they may each be referring to as ‘degradation rate-encoding’ physical cells). In practice, the adjacent physical cells 308b-c may (at least indirectly) carry some information (see below).

As noted above, this example is in the context of an example of a flash memory. In this example flash memory, a physical cell 308 is ‘programmed’ if the physical cell 308 indicates a bit value of ‘0’ and ‘cleared’ if the physical cell 308 indicates a bit value of ‘1’ (thus if all logical cells 306 indicate 1 s then the memory device 302 is in the third logical state; however, if all logical cells 306 indicate a set of 0s and 1s, this may represent valid information over the estimated period of time). The physical cell 308 stores charge when programmed while the amount of charge stored is comparatively reduced when the physical cell 308 is cleared. Another scheme may involve a bit value of ‘0’ representing the ‘clear’ state and a bit value of ‘1’ representing the programming state, depending on the type of memory device 302 (thus if all logical cells 306 indicate 0s then the memory device 302 is in the third logical state; however, if all logical cells 306 indicate a set of 0s and 1s, this may represent valid information over the estimated period of time).

In such an example of a flash memory, a ‘transition’ from programmed to cleared may be possible whereas a transition from cleared to programmed may not be possible. In other words, a physical cell 308 may in some circumstances experience a ‘one-way’ transition, due to charge leakage, from 0 (programmed) to 1 (cleared). In this example where the first physical cell 308a stores charge to represent being programmed, the first physical cell 308a may be expected to potentially leak charge to the adjacent second and/or third physical cells 308b-c in some circumstances (e.g., depending on the amount of charge stored in the second and/or third physical cells 308b-c). The charge leakage effect may be such that the bit value (or analog value) indicated by the first physical cell 308a changes over time. In some examples, the ‘surrounding’ physical cells 308b-c may not be expected to leak fast enough to change state during the lifetime of information storage. However, this may depend on the relative amount of charge stored in the second and/or third physical cells 308b,c over time with respect to other physical cells 308 adjacent to the second and/or third physical cells 308b,c.

The speed at which the first physical cell 308a transitions from a programmed state to the cleartext state may be digitally encoded within each logical cell 306 via the amount of charge stored in the adjacent (‘degradation rate-encoding’) physical cells 308b-c. The second and third physical cells 308b-c may influence their associated first physical cell 308a by the relative amount of charge stored between the respective physical cells 308a-c. For example, any physical cell 308 programmed to indicate ‘0’ may transition to a ‘1’ if an adjacent physical cell 308 can receive the leaked charge. However, a physical cell 308 indicating ‘1’ may not leak charge and may not change its indicated value (unless it receives charge from an adjacent physical cell). In an example digital setting where the second and third physical cells 308b-c store two discrete values (0 or 1), the speed at which the first physical cell 308a is predicted to transition from 0 to 1 is digitally encoded in the three physical cells 308a-c making up the logical cell 306.

An example way to encode a relatively fast transition from programmed to clear may be to set the first physical cell 308a to indicate ‘0’ and the surrounding (degradation rate-encoding) second and third physical cells 308b-c to indicate ‘1’. Thus, the logical cell 306 may initially encode ‘101’ initially but transition to ‘111’ due to the charge leakage effect.

An example way to encode a relatively slow transition from programmed to clear may be to set the first physical cell 308a to indicate ‘0’ and the surrounding second and third physical cells 308b-c to also indicate ‘0’. Thus, the logical cell 306 may initially encode ‘000’ initially. The charge leakage effect may be minimized such that the transition takes a very long time (since the first physical cell 308a may not leak much charge into the surrounding physical cells 308b-c unless those surrounding physical cells 308b-c also lose charge (e.g., to another physical cell 308 of another logical cell 306).

Although bit values may be indicated via the ‘digital’ encoding scheme described above to control the rate of charge leakage, it may also be possible to encode a greater range of charge leakage rates by specifying an ‘analog’ value in the first physical cell 308a (e.g., by injecting different amounts of charge into the first physical cell 308a in such a way that does not necessarily represent a ‘digital’ encoding scheme). In other words, the number of charges in the surrounding physical cells 308b-c may not be set to two discrete values (indicating a ‘0’ or ‘1’) but could instead take a multiplicity of values (e.g., being measurable by the voltage across the first physical cell 308a).

As noted above, the set 304 of logical cells 306 may be in various ‘logical states’, depending on how the data values have been written to the memory device 302. The logical state may refer to the collective state of the set 304 of logical cells 306. In this context, the term ‘logical state’ may refer to the state of multiple logical cells 306 instead of the individual state of the physical cells 308.

In some examples and as referred to above in relation to FIG. 3, there may be three logical states.

The ‘first’ logical state may refer to a so-called ‘cleartext state’ in which the first physical cells 308a (of the set 304 of logical cells 306) carry the exact value of the data, meaning that the data is in a cleartext form. For example, the set 304 of logical cells 306 may indicate either a 0 or 1 (e.g., making up the ‘valid’ information).

The ‘second’ logical state may refer to a so-called ‘hidden state’ in which all of the first physical cells 308a (in the set 304) are set to ‘0’ and are ‘programmed’. This second logical state represents a hidden state because thanks to the encoding described above, it cannot be assumed that the first physical cell 308a is to stay at ‘0’ or transition to ‘1’. The information may be represented by a set of data values, which could be a sequence of 0s and 1s. Unless the second and third physical cells 308b-c of each logical cell 306 of the set 304 can be read (which might be prevented as discussed below), it may not be straightforward to ascertain which (subset) of the logical cells 306 of the set 304 truly represent a ‘0’, and which (other subset of) of the logical cells 306 of the set 304 are expected to transition to ‘1’ at some point in time (at which point the entire set 304 may potentially represent valid information).

The ‘third’ logical state may refer to a so-called erased state in which all of the first physical cells 308a (in the set 304) are set to ‘1’ and are erased. It is unlikely that the first physical cells 308a are to change to another state from the ‘erased state’. The surrounding second and third physical cells 308b-c may carry some information about prior states (and thus some information about the clear text). As highlighted above, it may be useful to control access to the second and third physical cells 308b-c (or erase them) since they may carry information that may reveal the previous state of the first physical cell 308a.

In view of the possibility of charge leakage occurring between adjacent physical cells 308, there may be various possible transitions between the logical states. Three possible transitions are described below.

An example transition may be from the ‘hidden state’ to the ‘cleartext state’. In the initial state, all the logical cells 306 of the set 304 store ‘0’s. In the end state, the bits of the cleartext that store a ‘1’ have their logical cell 306 (of one subset of the set 304) that transitioned from ‘0’ to ‘1’. The bits of the cleartext that are set to ‘0’ did not experience a transition in their logical cell 306 (of another subset of the set 304). It may be understood that the logical state is stored in the surrounding physical cells 308b-c, which means that in the hidden state, the value of a bit is physically stored thanks to the encoding described above.

Another example transition may be from the ‘cleartext state’ to the ‘erased state’. In the initial state, the logical bits carry the set of data values representative of the valid information. However, any of the logical cells initially storing a ‘0’ transition to ‘1’, to become erased. A bit initially at ‘1’ does not change state. In the end state, all bits are set to ‘1’ such that there is content.

Another example transition may be from the ‘hidden state’ to the ‘erased state’. In this example transition, all the bits transition from ‘0’ to ‘1’. The initial data represented by the set 304 is all ‘0’s for each logical cell 306 of the set 304; and the final data is all for each logical cell 306 of the set 304. There are two scenarios where this example transition may be implemented.

In a first example scenario, the example transition is via the ‘cleartext state’. The initial state may be the hidden state (all logical cells 306 of the set 304 indicate ‘0’s); the intermediate state is the cleartext state (the logical cells 306 of the set 304 hold the data bit value); and the final state is the erased state (all logical cells 306 of the set 304 indicate 1's). This first example scenario may refer to the example ‘window of time’ in which the information goes from being invalid/partially valid (i.e., ‘hidden’) to valid (i.e., ‘clear’) to invalid (i.e., ‘erased’).

In a second example scenario, the example transition is not via another state but instead is a direct transition. Thus, the transition is directly from the hidden state to the erased state. Although some data may never be revealed and so never used, there may be some cases where data could be revealed if a condition is met before a timeout occurs. For example, a certain read/write sequence pattern applied to the memory device 102 may alter the degradation rate of certain logical cells 306 such that the timeout occurs at another time to reveal the data. However, the information may be deleted using the degradation mechanism if the condition was not met at timeout (or another parameter the leads to charge leakage).

Although the above description refers to clear cut, distinct states, in reality there may be more than one state at any time. Hence, the ‘period of time’ is estimated since there may be a certain amount of time where not all of the logical cells 306 of the set 304 that are expected to transition have actually transitioned. In other words, the information indicated by the set 304 of logical cells 30 could however be in between two states, meaning that some logical cells 306 may carry the bit value of the cleartext while others are in a hidden state (e.g., in the hidden to clear transition) or an erased state (e.g., in the clear to erased transition).

Some examples related to the above description of the state transitions are described below.

In some examples, the charge stored by each first physical cell 308a of the set 304 of logical cells 306 when in the first logical state corresponds to a bit value of 0 or 1 and represents a valid data value making up part of the information.

In some examples, the charge stored by each first physical cell 308a of the set 304 of logical cells 306 when in the second logical state corresponds to a bit value of 0, irrespective of whether the charge stored is indicative of a valid data value or an invalid data value.

In some examples, the charge stored by each first physical cell 308a of the set 304 of logical cells 306 when in the third logical state corresponds to a bit value of 1.

In some examples, in use of the apparatus 300, the set 304 of logical cells 306 is to transition from the second logical state to the first logical state at a start time of the estimated period of time. This example may correspond to the hidden to cleartext transition example (e.g., the initial set of data values stored represent invalid/partially valid information and a later set of data values stored after the transition represent valid information).

In some examples, in use of the apparatus 300, the set 304 of logical cells 306 is to transition from the first logical state to the third logical state after the estimated period of time has elapsed. This example may correspond to the clear to erased transition example (e.g., the initial set of data values stored represent valid information and later on the set of data values stored are erased after the transition).

In some examples, in use of the apparatus 300, the set 304 of logical cells 306 is to transition from the second logical state to the first logical state at a start time of the estimated period of time. Further, the set 304 of logical cells 306 is to transition from the first logical state to the third logical state at an end time of the estimated period of time. This example may correspond to the hidden to erased transition (via the cleartext state) example (e.g., the set of data values stored represent valid information for a window of time but are invalid/erased before/after each transition, respectively).

An explanation is now given on how certain transition examples may be applied to the example where the ‘information’ comprises access data such as a cryptographic key where a cryptographic key may be stored in the memory device 302 that provides configurable degradation over time. The content itself (i.e., ‘data of interest’) may be stored in an encrypted form on a resilient storage (e.g., within the apparatus 300 or another device).

In some examples, at least one part of the key may be set to lose content over different time periods (or in response to another parameter such as an access sequence pattern—e.g., read/write memory operations). Charge leakage may result in some bits of the key that were set to ‘0’ (programmed) transitioning to ‘1’ (cleared). At a given point in time, the key may have some parts that are still valid while others may be erased. In this situation, some cryptanalysis may be needed to recover the full key, if feasible. The encrypted content may therefore be more difficult to access than earlier in time.

In some examples, to make a key ‘appear’ over time, the key may be programmed with an array of ‘0’s. The bits of the key whose value is ‘1’ may be set (via the ‘surrounding’ physical cells 308b-c of the relevant subset of logical cells 306) to change value after some time, meaning that the physical cells 308a holding their value are expected to lose charges (e.g., in their floating gate) to thereby transition from ‘0’ to ‘1’.

In some examples, to implement a window with a specified period of access time, the set 304 of logical cells 306 indicate all ‘0’s initially. A first subset of the first physical cells 308a of the set 304 that are expected to transition to ‘1’ are expected to transition from indicating ‘0’ to ‘1’ after some time t_1 based on the rate of charge leakage associated with the first subset. A second subset of the first physical cells 308a of the set 304 are expected to transition from indicating ‘0’ to ‘1’ after some time t_2>t_1 based on the rate of charge leakage associated with the second subset. Thus: prior to t_1, all logical cells 306 indicate a bit value of ‘0’; between t_1 and t_2 the first subset indicates the bit value ‘1’ and the second subset indicates the bit value ‘0’ (and the first and second subset may represent the valid data values between t_1 and t_2); and after t_2 all logical cells indicate the bit value ‘1’.

In a related example, an explicit mechanism (such as a memory operation) may be implemented at time t_1 to set the bits currently at ‘0’ to the value ‘1’ with a timeout (via the surrounding physical cells 308b-c that may cause these physical cells 308a to switch to ‘0’ again at time t 2). The memory operation such as a read and/or write operation (or a sequence of read and/or write operations) may change the relative amount of charge stored in the first physical cell 308a and the surrounding physical cells 308b-c such that the duration of the timeout can be set based on the rate of charge leakage.

A memory read operation may be implemented to read a physical cell 308a-c (where access is provided). In this case, all the physical cells 308a-c in series/in a string with the target physical cell that are to be read (e.g., at least one of the physical cells 308a-c) need to have a voltage applied on their gate so that they are open/conducting. This voltage may be high enough to conduct whatever the state (0 or 1) of the physical cells 308a-c in the series. This voltage, even if smaller than the one used to program may at least partially program the physical cells 308a-c in the series (i.e., add a small amount of charge to some physical cells 308a-c but not enough to flip from a 1 to a 0). Thus, in some cases, reading a physical cell 308a-c may lead to certain physical cells 308a-c in a page becoming at least ‘partially’ programmed. Partially programmed may mean that the physical cell 308a-c still reads a ‘1’ but the amount of charge stored may be more than usual for an unprogrammed physical cell 308a-c. In some cases, this increase in stored charge in a surrounding physical cell 308b-c may lead to a reduction in the relative charge stored between the first physical cell 308a and the second and third physical cells 308b-c (which may delay the transition of the first physical cell 308a indicating a bit value of ‘1’ after initially indicating a bit value of ‘0’).

A memory write operation may be implemented to write to a first physical cell 308a. In this case, a relatively higher voltage (compared with the read operation) may be applied on the gate of the target first physical cell 308a. As all the first physical cells 308a in a given position in the different pages share the bit line, a physical cell 308b-c in each other page has a high voltage applied on their gate. To prevent these other physical cells 308b-c from being programmed, a mid-range voltage may be applied to the bit lines of the physical cells 308b-c directly surrounding the target first physical cell 308a. This may have the consequence of changing the overall voltage of the pages not being targeted and prevent the high voltage on the target bit line from programming the physical cells 308b-c of the non-target pages. However, the process may not work quite as expected and the physical cells 308b-c of the targeted bit line representing non-targeted pages may still get at least partially programmed. Thus, in some cases, the second and third physical cells 308b-c surrounding the target first physical cell 308a in the page may also be at least partially programmed (slightly) and, as a result, affect the rate of charge leakage in a similar manner to that described above.

Thus, there may be examples where performing a read and/or write operation on a physical cell 308a can lead to programming some other physical cells 308b-c. An example consequence is that accessing a given physical cell 308a may slightly impact the surrounding physical cells 308b-c. In some cases, one logical cell 306 comprising three physical cells 308a-c where a page comprises a series of three-transistor physical cells 308a-c, it may be possible to read a logical cell 306 to modify the leakage rate as this may impact the charge stored in the ‘timing’ second and third physical cells 308b-c. In some cases, some other adjacent physical cells (not within the three-physical-cell logical cell 306) may be tailored to impact the ‘timing’ physical cells 308b-c. Thus, further charge leakage between these other adjacent physical cells and the ‘timing’ physical cells 308b-c may further influence the amount of charge stored in the ‘timing’ physical cells 308b-c.

An example implementation may be a five-physical-cell logical cell where the central ‘first’ physical cell 308a is data-holding; the surrounding ‘second and third’ physical cells 308b-c are for controlling the timing of any transition of the first physical cell 308a; and further surrounding ‘fourth and fifth’ physical cells (not shown) respectively adjacent to the second and third physical cells 308b-c may influence the timing operation. The five physical cells may share the same bit line.

Thus, it may be possible to perform a memory operation with respect to the fourth and fifth physical cells that increases or decreases the amount charge stored in the ‘timing’ physical cells 308b-c (which may have the effect of increasing or decreasing the time before the first physical cell 308a transitions from a ‘0’ to a ‘1’ where the first physical cell 308a is initially programmed to ‘0’.

In some examples, knowledge of the amount of stored charge, currently stored data values and/or how the memory operations affect the amount of stored charge may be exploited in order to implement various functionality such as locking the logical cells 306 from programming while a ‘secret’ pattern of read and/or write memory operations (where the pattern may specify which memory operations to perform in which order and on what physical cells to perform the memory operations) may affect the rate of charge leakage to thereby control the timing of any data transitions as described herein.

In some examples, a disturbance caused by a memory operation may add charges to the ‘timing’ physical cells 308b-c, hence slowing down any transition to the cleartext state of the first physical cell 308a. Such a memory operation may facilitate access control of the erasure timing when the programming to the ‘timing’ physical cells 308b-c is not available for some reason. This lack of availability to control the ‘timing’ physical cells 308b-c may be because a user attempting to change the timings is not privileged enough to change the timing value sufficiently, and so may instead change the timing value in relatively small increments through the read and/or write operations. In some cases, the ‘timing’ physical cells 308b-c may have been locked in a certain way after being programmed, and so a subsequent memory operation may represent a way to modify them if direct programming access is otherwise prevented for some reason.

In some examples, such a ‘disturbance’ may provide a way for the party which programmed the timings to postpone the appearance of a secret value. This could be useful for values that do not need to be erased once revealed. It could be that the value was programmed to be revealed at a given point but it is decided at a later point in time that the secret value may be accessed later than originally planned. The party managing the secret and relying on it not being revealed before the given time would have a mechanism to postpone its release. An attacker may not have an incentive to use the mechanism as this may result in the value being kept secret for even longer. The mechanism may provide a way to tamper with the timing with reduced security issues since using the mechanism may be contrary to the attacker's interest. In this regard, a fourth and/or fifth physical cell may be allocated for the task of controlling the amount of charge stored in the ‘timing’ physical cells 308b-c.

In some examples, it may be useful to determine that the secret is public knowledge once revealed (not following erasure). This could be used as a mechanism to restrict the number of accesses to the secret before it is released. There may be cases where the secret can be used for a computation but is not revealed in cleartext (so may not be copied). The secret could have been partially revealed (e.g., with some bits cleared) but the secret may not be usable as far as all the bits have not been revealed (because relying on the longest timing out may be considered a secure strategy). An attacker could however try to recover the key with a partially revealed key by computing many inputs with the partially revealed key to mount a cryptanalysis. The more bits that are revealed, the easier the cryptanalysis. Many accesses to the key may increase the timing for appearance of the not yet revealed bits. So the attacker could have an incentive to wait for the key to appear rather than try to mount a cryptanalysis. Even in the case, where the key has enough bits revealed for a cryptanalysis to be easily done, the attacker may still be taking the risk of accessing the key too early and jeopardize any possible key recovery (making the assumption that the key cannot be read and that the cryptographic computation with a key which has one bit which is wrong does not reveal any more information on the number of wrong bits in comparison to a key where half of the bits are wrong).

An explanation is now given on how certain transition examples may be applied to implementing error correction for facilitating data recovery (e.g., where the information is the ‘data of interest’) in case of the logical state being the erased state.

In some examples, at least one part of the information (stored as cleartext such as ‘data of interest’) may degrade at a given rate due to the charge leakage effect. At least one of the ‘flipped’ bits (i.e., the logical cells 306 indicating ‘0’s that have transitioned from clear to erased) may be corrected with an error correction code (ECC) if the error rate is low enough (for example, fewer than three errors in the data associated with an ECC tag). In an example, the ECC may be accessible to an authorized entity to allow the authorized entity to recover the flipped bits. In some examples, the ECC may be tailored to recover data with a given performance dependent on the number of errors (for example, restricting the performance of recovery). This example may be useful for facilitating data recovery where data is not or is unable to be encrypted. This example may also facilitate a more granular data tampering than the cryptographic key example described above. In the cryptographic key case, this may be considered an all or nothing situation: if the key is recovered the data is fully recovered; if the key cannot be found, the data is lost (or at least it is expensive to recover). In the ECC case, the (unencrypted) information can be partially lost but may still be at least partially recoverable with or without the ECC.

An explanation is now given on how certain transition examples may be applied to implementing data degradation to information such as a ciphertext.

In some examples, if one bit of the ciphertext were erased (i.e., a single ‘1’ may have been erased), an attacker may compute candidate ciphertexts (by independently flipping each 1 to be a 0) and attempt decryption on each candidate ciphertext. The more bits erased, the more candidate ciphertexts there are (i.e., if two bits are erased, the attacker could compute candidate ciphertexts by flipping every possible pair of ‘1’s to a ‘0’), and the more infeasible this decryption attempt would become. Past a certain degradation level, the content may be considered ‘lost’. This example could represent a way of erasing encrypted data over time (or after a succession of events) without erasing the cryptographic key associated to the data.

An explanation is now given on how certain transition examples may be applied to implementing time-varying data degradation.

In both the cryptographic key and the ECC cases described above, several pieces of data can be setup to have their degradation rate (or apparition rate) set with different timeout or access patterns. In the cryptographic key example, this may mean that the several pieces of data of interest are encrypted with keys that are stored with different degradation (apparition) rates. For the ECC example, this may mean that the different pieces of data are stored with different ECC tags checking for their integrity.

In some examples, a mix of data of interest may be stored based on the cryptographic key and ECC examples, with varying degradation functions (as a function of time, access patterns, etc.), and state transitions (data apparition or degradation) may be built in the same memory device 302. For example, a cryptographic key may be stored such that it is valid over an estimated period of time and the data of interest (where an ECC may be used to recover this data if it is partially erased) may be stored such that it is valid over a different estimated period of time.

In some examples, various assumptions may be made about the mechanisms for implementing certain examples described herein effectively.

Certain examples may specify that the data may not be copied. This matter is described below in the section on encryption of data in a memory device.

In some examples, the second and third physical cells 308b-c surrounding the first physical cell 308a may be inaccessible to an attacker. For example, writing to the second and third physical cells 308b-c could reveal hidden data. Write protection can be used to address this issue. In another example, reading the second and third physical cells 308b-c could reveal the data in cleartext as this may reveal the 3-bit encoding of a logical cell 306. Access control may be implemented to prevent the second and third physical cells 308b-c being accessible for reading and/or writing. The section below on the ‘interface’ may address at least partially address this matter.

Some further examples are described below. These examples may be related to certain other examples described above.

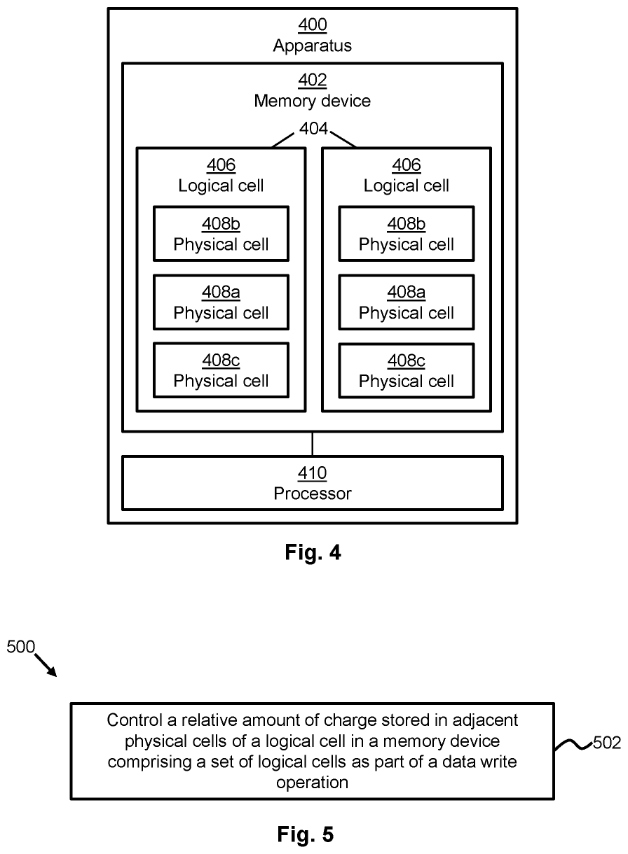

FIG. 4 is a schematic illustration of an example apparatus 400 for storing information. The apparatus 400 may be provided as a standalone device or as part of a system such as described in relation to FIG. 2. In some examples, the apparatus 400 may be communicatively coupled to an interface (as discussed below) for controlling memory operations carried out in the apparatus 400. The apparatus 400 may have the same or similar functionality and/or operate using the same charge leakage effect as described previously. In FIG. 4, reference signs for features of the apparatus 400 that are similar or like corresponding features of the apparatus 300 are incremented by 100 compared with FIG. 3.

The apparatus 400 comprises a memory device 402. The memory device 402 comprises a set 404 of logical cells 406. Each logical cell 406 of the set 404 comprises a data-holding first physical cell 408a and a second and third adjacent physical cell 408b-c for controlling a lifetime of a data value indicated by the first physical cell 408a. Charge stored in the second and third physical cells 408b-c controls a rate of charge leakage between the first physical cell 408a and the second and third physical cells 408b-c to control the lifetime of the data value stored in the first physical cell 408a.

The apparatus 400 further comprises a processor 410 to control (e.g., via the interface described herein) the amount of charge injected into the second and third physical cells 408a-b as part of a data write operation to write a set of data values to the set 404 of logical cells 406. The processor 410 is further to define the rate of charge leakage (e.g., via the interface), such that the set of data values indicated by the set 404 of logical cells 406 over an estimated period of time is representative of information that is valid over the estimated period of time. A start time and end time of the estimated period of time is defined by the rate of charge leakage.

In an example, the processor 410 may implement certain functionality of an interface with the memory device 402 (such as described below). For example, the processor 410 may provide a way to interact with the memory device 402 such that memory operations can be performed. In an example, the processor 410 may have access to stored instructions (e.g., in the memory device 402 or another memory device accessible to the processor 410) readable and executable by the processor 410 to implement the functionality described above. In some examples, the processor 410 may implement the functionality of any of the other examples described herein such as described in relation to the section on validity of information stored in memory devices, the section relating to interfacing with memory devices and/or the section relating to encryption of data in memory devices.

FIG. 5 depicts a flowchart of an example method 500 of storing information. The method 500 may be a computer-implemented method (e.g., implemented using processing circuitry). In some examples, the method 500 may be implemented by (e.g., a processor of) the interface as already mentioned and as described in more detail below. Reference is made to certain features of FIG. 1 in the description of FIG. 5.

The method 500 comprises, at block 502, controlling (e.g., as part of a memory operation such as a data write operation) a relative amount of charge stored in adjacent physical cells 108a, 108b of a logical cell 106 in a memory device 102 comprising a set 104 of logical cells 106.

The amount of charge stored in a data-holding physical cell 108a of the logical cell 106 is indicative of a data value. The memory operation provides the set 104 of logical cells 106 in an initial logical state and the set 104 of logical cells 106 may be transitionable to at least one other logical state (although some logical cells 106 may not transition due to their initial state such as initially indicating a bit value of ‘1’) after leakage of charge between the adjacent physical cells 108a, 108b within the set 104 of logical cells 106. The relative amount of charge stored in the adjacent physical cells 108a, 108b defines (an estimated or approximate) charge leakage rate between the adjacent physical cells 108a, 108b. The charge leakage rate defines an estimated timing of a transition from the initial logical state to the at least one other logical state. A set of data values stored by the set 104 of logical cells 106 represents valid information when the set 104 of logical cells 106 is in one of the logical states. The set of data values stored by the set 104 of logical cells 106 represents at most partially valid information when the set 104 of logical cells 106 is in another of the logical states.

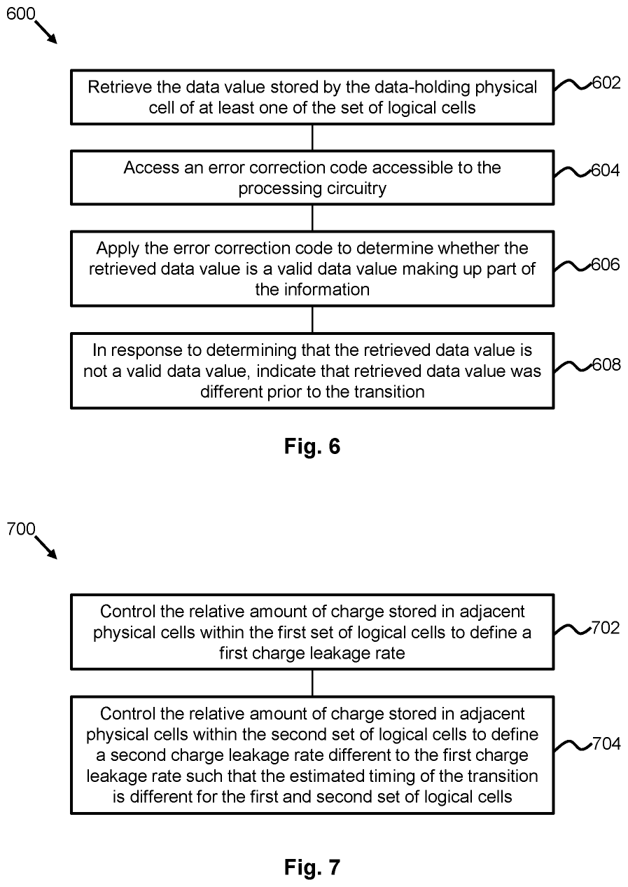

FIG. 6 depicts a flowchart of an example method 600 of applying an error correction code. The method 600 may be a computer-implemented method (e.g., implemented using processing circuitry). In some examples, the method 600 may be implemented by (e.g., a processor of) the interface as already mentioned and as described in more detail below. The method 600 may implement examples such as described above in relation to examples relating to the error correction code. Reference is made to certain features of FIG. 1 in the description of FIG. 6.

The method 600 may be implemented at some point in time after the method 500 has been implemented, i.e., after the transitioning from the logical state where the set of data values stored by the set 104 of logical cells 106 represents valid information to the other logical state where the set of data values stored by the set 104 of logical cells 106 represents at most partially valid information (for example, the set 104 of logical cells 106 may be in the hidden or erased state). In some examples, the method 600 may be implemented as an independent method with respect to the method 500.

The method 600 comprises, at block 602, retrieving the data value stored by the data-holding physical cell 108a of at least one of the set 104 of logical cells 106.

The method 600 further comprises, at block 604, accessing an error correction code (ECC) accessible to the processing circuitry (for example, an ECC stored in the memory device 102 or another memory device)

The method 600 further comprises, at block 606, applying the ECC to determine whether the retrieved data value is a valid data value making up part of the information.

The method 600 further comprises, at block 608, in response to determining that the retrieved data value is not a valid data value, indicating that retrieved data value was different prior to the transition.

FIG. 7 depicts a flowchart of an example method 700 of defining different charge leakage rates. The method 700 may be a computer-implemented method (e.g., implemented using processing circuitry). In some examples, the method 700 may be implemented by (e.g., a processor of) the interface as already mentioned and as described in more detail below. The method 700 may implement examples such as described above in relation to making different parts of information valid at different times (e.g., by defining different charge leakage rates). Reference is made to certain features of FIG. 1 in the description of FIG. 7.

In this example, the memory device 102 comprises a first set of logical cells 106 for storing a first portion of the information and a second set of logical cells 106 for storing a second portion of the information. In other words, the set 104 of logical cells 106 may be logically divided into the first and second set of logical cells 106.

The method 700 comprises, at block 702, controlling (e.g., as part of a memory operation such as a data write operation) the relative amount of charge stored in adjacent physical cells 108a, 108b within the first set of logical cells 106 to define a first charge leakage rate

The method 700 comprises, at block 704, controlling the relative amount of charge stored in adjacent physical cells 108a, 108b within the second set of logical cells 106 to define a second charge leakage rate different to the first charge leakage rate such that the estimated timing of the transition is different for the first and second set of logical cells 106. In this manner, certain parts of information stored in the first and second sets of logical cells 106 may be made valid for different estimated periods of time (i.e., different estimated start and end times). This concept may be extended to further sets (e.g., a third set of logical cells 106 in which another charge leakage rate is defined to make the part of information stored in the third set valid for a different estimated period of time).

Certain features of examples described above in relation to ‘validity of information stored in memory devices’ may be combined with, replace features of or incorporate features from examples described below in relation to ‘interfacing with memory devices’ and/or ‘encryption of data in memory devices’.

Interfacing with Memory Devices

As already mentioned, an interface may be provided to allow memory operations to be performed in a memory device such as a flash memory. Such an interface may follow a specification according to the type of memory device to be interfaced with.

Some example interfaces may be specified such as Open NAND Flash Interface (ONFI), which may be used with a controller such as used in Solid-State Drives (SSDs) or Universal Seral Bus (USB) memory sticks; Universal Flash Storage (UFS) interface; embedded Multi-Media Card (eMMC) interface; Non-Volatile Memory express (NVMe); Serial Advanced Technology Attachment (SATA); Small Computer System Interface (SCSI), etc.

As described above, a memory device is proposed to provide information in a valid form over an estimated period of time due to a charge leakage effect that may change data values stored in physical (memory) cells of the memory device over time.

This section describes the implementation of an interface for facilitating the functionality of the memory device described above. The interface may facilitate control over memory operations and/or access to certain physical cells. For example, accessing the ‘degradation rate-encoding’ physical cells could, in certain circumstances, reveal or hint at a hidden data value representing part of the information or an erased data value. Therefore, the interface may manage or restrict access to these degradation rate-encoding physical cells to maintain trust in the security of the memory device.

Due to the logical structure described herein (e.g., the physical cells are organized into sets of logical cells where a data value is stored in each logical cell) the example interfaces described herein may ensure that a logical cell is addressed as part of a memory operation while handling the control of charge stored in the degradation rate-encoding physical cells.

In an example data write operation, all physical cells of a memory device could be accessed in the same way. However, for the purpose of data writing to a physical cell, there may be a degree of programming difficulty for the examples described herein. For example, a programmer may need to think about which physical cells in a block are data-holding ‘first’ physical cells and which ones are degradation rate-encoding physical cells. This approach may lead to errors and/or could be prone to tampering by attackers. In addition, a programmer may need to consider managing the memory device such as by performing wear leveling, which may in some examples be implemented at the physical cell level.

In an example data read operation, the read command may be security sensitive since content accessed might be from pages storing data (representative of the information) or from ‘degradation rate-encoding’ pages that encode the rate at which data values might change in the data-holding pages.

Examples described herein may provide an interface for facilitating the functionality of the examples described above while also reducing various risks or issues associated with this functionality.

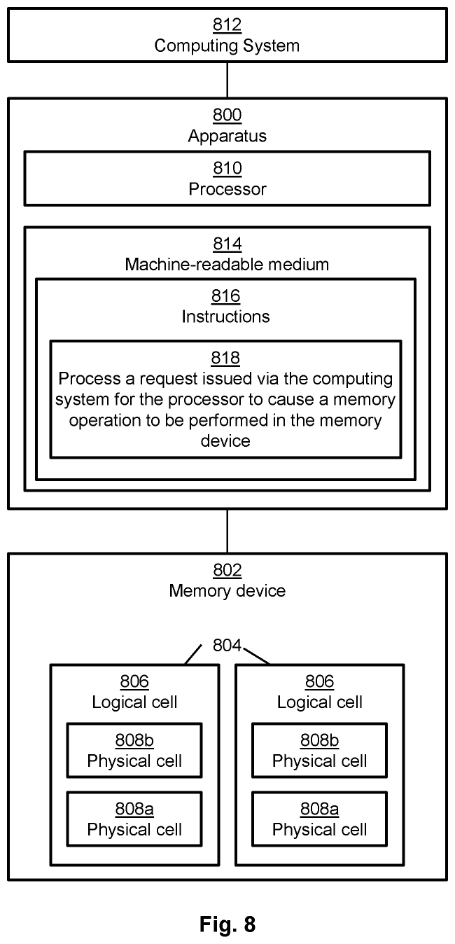

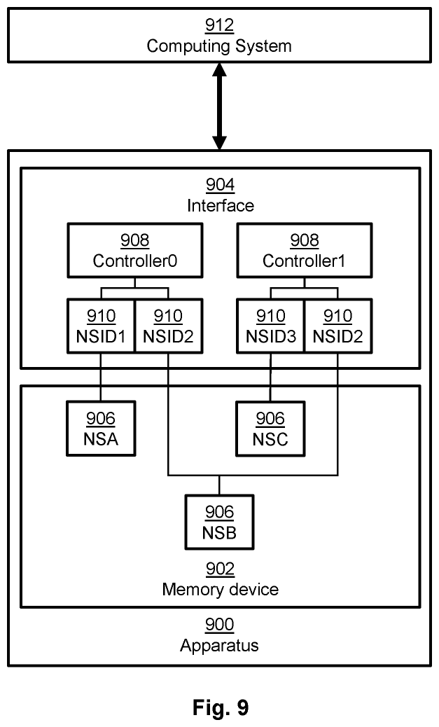

FIG. 8 is a simplified schematic drawing of an example apparatus 800 for providing an interface to a memory device 802. The memory device 802 may comprise a features or functionality of any of the examples described herein. In FIG. 8, reference signs for features of the apparatus 800 that are similar or like corresponding features of the apparatus 100 are incremented by 700 compared with FIG. 1.

The apparatus 800 comprises a processor 810 to interface with a computing system 812 (e.g., to interface with processing circuitry of a computing system such as described in relation to FIG. 2) and the memory device 802. In some examples, the processor 810 may implement functionality such as described in relation to the interface 204 of FIG. 2 and/or the processor 410 of FIG. 4 (or any other processing circuitry described in relation to other examples).

The memory device 802 comprises a set 804 of logical cells 806. A logical cell 806 of the set 804 of logical cells 806 indicates a data value by an amount of charge stored in a physical cell 808a of the logical cell 806. Charge leakage between the physical cell 808a and an adjacent physical cell 808b of the logical cell 806 is to occur at a rate that at least partially depends on a relative amount of charge stored in the physical cell 808a and the adjacent physical cell 808b.

The apparatus 800 further comprises a machine-readable medium 814 storing instructions 816 readable and executable by the processor 810. The instructions 816 comprise instructions 818 to cause the processor 810 to process a request issued via the computing system 812 for the processor 810 to cause a memory operation to be performed in the memory device 802.

For example, a user of the computing system 812 may want information (e.g., ‘access data’, ‘data of interest’, etc.) to be written to or read from the memory device 802. The computing system 812 may generate a request for the user and send the request to the apparatus 800. In some examples, such a request may indicate a period of time over which the information in the request is to be valid for. The apparatus 800 may process such a request and issue a command which acts on the memory device 802 in accordance with the request, e.g., if such a request is authenticated by the apparatus 800.

In some examples, the apparatus 800 and other examples described below may handle the interaction with the set 804 of logical cells 806 during a data write operation to facilitate writing a set of data values corresponding to the information while also encoding the period of time over which the information is estimated to be valid. Accordingly, certain examples described herein may facilitate write protection for the physical cells in a logical cell for storing a data value; may prevent tampering with the conditions which define the transition (i.e., the amount of charge); and/or may reduce security vulnerabilities which may otherwise affect the time over which the information is valid or allow data values making up part of the information to be determined or somehow inferred by an attacker.

In some examples, the apparatus 800 and other examples described below may handle the interaction with the set 804 of logical cells 806 during a data read operation to facilitate reading a set of data values from the memory device 802 in such a way that the present data values can be read while preventing encoded data regarding the charge leakage rate from being exposed. Accordingly, certain examples described herein may facilitate read protection for the physical cells in a logical cell, which may prevent an attacker or other actor intentionally or accidentally reading sensitive physical cells which potentially encode the actual value of the data-holding physical cell.

In some examples, the apparatus 800 and other examples described below may make it easier to manage the memory device 802, for example, via firmware running in a controller (corresponding to the apparatus 800) of the memory device 802 or on the computing system 812 e.g., for hosting the memory device 802.

In some examples, the apparatus 800 and other examples described below may facilitate security provision by providing some low-level commands that may help to secure the stored data and/or prevent or reduce the likelihood of an unauthorized entity from accessing the stored data and/or the encoding of the charge leakage rate.

FIG. 9 is a simplified schematic drawing of an example architecture for an apparatus 900. The apparatus 900 comprises a memory device 902 and an interface 904. The features of the apparatus 900 may correspond to various examples described herein. For example, the memory device 902 may implement the functionality of any other examples of memory device described herein. The interface 904 may implement the functionality of any other examples of interface (or processing circuitry for implementing the interface functionality) described herein.

The architecture may be based on the NVMe specification although other architectures could be implemented by the memory device 902.

The memory device 902 comprises physical cells (not shown) such as described above. The physical cells are logically divided into a set of namespaces (NS) 906 of which three are depicted in this example and are labelled NSA, NSB and NSC. Each namespace may comprise a set of physical cells. In some examples, at least one of these namespaces may be addressable in terms of ‘logical cells’ as described herein. There may be fewer or more namespaces in any memory device 902. Some physical cells of the memory device 902 may be unallocated (i.e., not in any namespace).

The interface 904 comprises logical controllers 908, labelled ‘controller0’ and ‘controller1’. Each logical controller 908 may be implemented by processing circuitry such as associated with the interfaces as described in other examples. There may be fewer or more logical controllers 908 in any interface 904, for example, depending on how many namespaces 906 exist.

In this example, the controllers 908 each address certain namespaces 906 via a namespace ID (NSID) 910. The NSID 910 is accessible to the respective controller 908 and represents an identifier used by the controller 908 to facilitate access to an associated namespace 906. In this example, there are three NSIDs 910 (labelled NSID1, NSID2 and NSID3) providing a link to the three depicted namespaces 906. A namespace 906 may be associated with at least one of the controllers 908 via these NSIDs 910. In this example, NSA 906 is associated with controller0 908 via NSID 1 910, NSB 906 is associated with controller0 908 via NSID2 and controller1 908 also via NSID2, and NSC 906 is associated with controller1 908 via NISD3. Therefore, NSA 906 is controllable by controller0 908, NSC 906 is controllable by controller1 908 and NSB 906 is controllable by both controller0 908 and controller1 908.

The interface 904 may provide a ‘port’ for allowing requests and data to be communicated with a computing system 912 (e.g., like or similar to the computing system 200 of FIG. 2 or the computing system 812 of FIG. 8). In use of the apparatus 900, the interface 904 may control access to the namespaces 906 and implement the functionality of certain examples described herein such as managing requests from the computing system 912, controlling how and in which physical cell (of a logical cell) a data value is to be read/stored and/or encoding a charge leakage rate in a logical cell.

A further explanation of certain functionality of the apparatus 900 is provided below.

Commands issued by the interface 904 (via a controller 908) may explicitly deal with logical bits and data value degradation (e.g., timing of a transition based on the charge leakage rate). The interface 904 may hide the details of the management of physical cells (e.g., including management of the data-holding physical cell that holds the value of a logical bit and the degradation rate-encoding physical cell(s) that specify whether the value is to change). In some examples, such a command abstraction may be for a certain namespace 906 in the memory device 902 whereas another namespace 906 may be controlled by a different set of commands (e.g., where reading from all physical cells may be permitted).

The commands for facilitating various memory operations in the memory device 902 are now discussed. Reference is now made to the example apparatus where there are three physical cells per logical cell (see FIGS. 3 and 4). However, the commands may be modified according to the number of physical cells per logical cell.

In some examples as referred to above, three physical cells make up a logical cell and are adjacent to each other in a cell string (e.g., a flash string in the case of flash-based memory). This means that programming a (single) logical page (e.g., comprising a set of logical cells) corresponds to programming three physical pages that are next to each other in a block (e.g., a flash block in the case of flash-based memory).

A ‘write’ command issued by the interface 904 may use three parameters: the value of a page, the ‘logical’ address of a page and the rate change condition. The value of a page may correspond to a parameter given in a command used for writing data values to individual physical cells. The logical address may define the targeted physical block and the ‘logical page’ in this block.

An example model for writing data to a physical block is now described.

A physical block may either store ‘enhanced’ physical cells (e.g., organizable into logical cells) or ‘non-enhanced’ cells (e.g., not organizable into logical cells but instead the physical cells may each hold data values). According to the example where there are three physical cells per logical cell (the ‘enhanced’ case), there may be three times fewer logical pages in a block than there are physical pages (and hence it takes three times more cells to store the same amount of data as in non-enhanced cells). This also means that the range of targetable addresses may be (about) three times smaller. A command may point to individual physical pages via a physical page offset command. For example, three adjacent logical pages may be pointed to by the respective offset commands, ‘3*physical_page_offset’, ‘3*physical_page_offset+1’ and ‘3*physical_page_offset+2’ (where the factor of ‘3’ is due to there being three physical cells per logical cell). In this example, the physical cells of the physical pages that correspond to the data-holding physical cells are pointed to by the command ‘3*physical_page_offset+1’ while the other commands point to the physical cells of the physical pages that comprise the degradation rate-encoding physical cells.

Each block may be associated with a metadata flag (e.g., accessible to the interface 904) that informs about the ‘enhanced’ vs. ‘non-enhanced’ state of the block. Addressing an ‘enhanced block’ may involve use of a command according to various examples described herein, which may reduce the likelihood of an error whether writing to a ‘non-enhanced’ block or a ‘enhanced’ block.

A ‘read’ command issued by the interface 904 may implement various functionality to ensure confidentiality (by preventing reading of the degradation rate-encoding physical cells), to facilitate access control (i.e., access control to logical data) and/or to verify or attest to the expected data degradation rate due to the charge leakage effect. In an example, a read command may facilitate access control dependent on an outcome of a separate authentication process (e.g., by single or multi factor authentication) implemented by the interface 904 to verify a user attempting to make the interface 904 execute the read command. In some examples, the interface 904 may perform a memory operation (or not perform a memory operation) to prevent data degradation if the user is successfully authenticated. However, the interface may perform a memory operation (or not perform a memory operation) to cause data degradation if the authentication process is unsuccessful.

In read prevention, a command may prevent the degradation rate-encoding physical cells from being read. For example, a read command may be modified by an ‘offset’ such as described above to prevent any read command from pointing directly to the degradation rate-encoding physical cells. In other words, the command may ensure that the value of logical cells in a block may be accessed rather than all individual physical cells in the block (when ‘enhanced’).

In access control, any requests from the computing system 912 may need to be authenticated before a command is issued based on the request. Such an authentication system may be implemented by the interface 904.

In an example, the interface 904 may authenticate a user using a digital signature scheme. For example, the user (of the computing system 912) may use a private key to sign a (fresh) command. The associated public key (i.e., ‘verifying data’) may be accessible to the interface 904 to allow verification of the signature. The public key may be stored elsewhere, or in a location corresponding to an area of the memory device 902 the user is trying to gain access to.

In another example that may use less memory, the user may be authenticated by a password. For example, a (potentially short) fingerprint of the password (i.e., ‘verifying data’) may be stored alongside the part of the memory device 902 the user is trying to access. In this case, the user may input the password to the computing system 912. At least part of the password may be communicated with the request and the interface 904 may compute the fingerprint of the password and compare it to the stored fingerprint.

In a verification/attestation operation, it may be possible to probe the degradation/apparition policy (i.e., the expected data degradation rate). Such a command may read the state of the data-holding physical cells and the related degradation rate-encoding physical cells to estimate the timing of any state transition. For example, the interface 904 may have access to data indicated estimated lifetimes of programmed physical cells based on the relative amount of charge stored in the data-holding physical cells and the adjacent degradation rate-encoding physical cells. The interface 904 may enforce that an estimate of the transition time is given rather than the ‘raw’ output which might otherwise lead to compromising data. The verification command may be used to verify the expected degradation rate, transition time, etc., while the attestation may attest to the expected degradation rate, transition time (e.g., in response to a request from the user associated with the computing system 912).

In an erase operation, the command may take into account whether it is a data-holding physical cell whose data is to be erased and/or a degradation rate-encoding physical cell whose data is to be erased. As already mentioned, erasing the data stored data-holding physical cell might not prevent recovery based on the data stored in the adjacent degradation rate-encoding physical cell. In any of these examples, the command may point to whichever physical cell is to be erased, depending on the scenario.

In an example, the erase command may cause a clean erase of the data-holding physical cells in the memory device 902. Erasure may mean that the threshold voltage of a physical cell went below the value at which it is read as a ‘1’ (erased state). However, before programming physical cells again, it might be useful to put them at a given threshold voltage which is even lower. Such an approach may ensure that cells that got naturally erased and left cleared (bit set to 1) do not have a threshold voltage that is too close from the one that otherwise reads a 0. Certain variations of the threshold voltage (for example a read disturb) could otherwise make the cell switch to 0.

In another example, the data in the degradation rate-encoding physical cells may be erased by the command. This may be in addition to, or instead of, the command to erase the data in the data-holding physical cells.

It is already stated that there may be circumstances where it may be useful to erase data in the degradation rate-encoding physical cells to reduce the likelihood of unintentional data disclosure even after the data-holding physical cells' data has been erased or hidden. Therefore, a command to delete a data value may point to all of the physical cells in a logical cell in order to set the bit values to ‘1’ in each physical cell. This way, the degradation rate-encoding physical cells may not reveal anything about a previous data value or expected data value of the data-holding physical cell.

Erasure in NAND memory devices may happen at the granularity of a block. In the example given previously, there may be three physical pages making up a logical page and are in the same block. A command to erase the block may ensure erasure of all of the physical cells in a logical cell in the erased block.

In some examples, the execution of the erase command may erase the associated ‘enhanced’ metadata flag associated with the block so that the block can be made available in a page pool rather than implementing separate page pools (i.e., one for enhanced blocks and another for non-enhanced blocks). In other examples, separate page pools may be implemented for enhanced blocks and non-enhanced blocks.

Some examples relating to the above are described below.

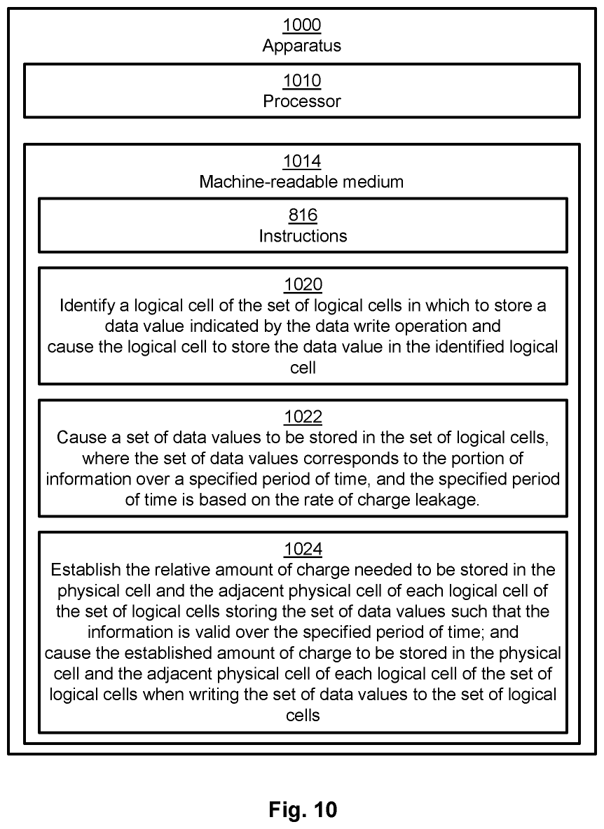

FIG. 10 is a simplified schematic drawing of an example apparatus 1000 for providing an interface to a memory device (e.g., the memory device 802 as depicted by FIG. 8, to which reference is made). In FIG. 10, reference signs for features of the apparatus 1000 that are similar or like corresponding features of the apparatus 800 are incremented by 200 compared with FIG. 8.

The apparatus 1000 comprises a processor 1010 and a machine-readable medium 1014. The machine-readable medium 1014 stores instructions 816 to cause the processor 1010 to implement certain functionality described in relation to the apparatus 800 of FIG. 8.

Further instructions are described below. Certain instructions may be omitted or implemented in a different order to that depicted by FIG. 10. Functionality relating to certain other examples described herein may be implemented by corresponding instructions stored in the machine-readable medium 1014.

In some examples, where the memory operation comprises a data write operation, the machine-readable medium 1014 stores instructions 1020 to cause the processor 1010 to identify a logical cell 806 of the set 804 of logical cells 806 in which to store a data value indicated by the data write operation. The instructions 1020 are further to cause the processor 1010 to cause the logical cell 806 to store the data value in the identified logical cell 806.

In some examples, the data write operation is to cause information to be written to the memory device 802, and the request provides an indication of a specified period of time (i.e., specified by a user performing the data write operation) over which the information is to be valid (although the period of time may be estimated once the request is executed in the memory device 802). In such examples, the machine-readable medium 1014 comprises further instructions 1022 to cause the processor 1010 to cause a set of data values to be stored in the set 804 of logical cells 806. The set of data values corresponds to the portion of information over the specified period of time (i.e., the set of data values may represent the information at a certain time within the period of time but may represent hidden or erased information outside the period of time). Further, the specified period of time is based on the rate of charge leakage.

In some examples, the machine-readable medium 1014 comprises further instructions 1024 to cause the processor 1010 to establish the relative amount of charge needed to be stored in the physical cell 108a and the adjacent physical cell 108b of each logical cell 806 of the set 804 of logical cells 806 storing the set of data values such that the portion of information is valid over the specified period of time (where the period of time is specified by the request and the actual period of time may be estimated). The instructions 1024 are further to cause the processor 1010 to cause the established amount of charge to be stored in the physical cell 108a and the adjacent physical cell 108b of each logical cell 806 of the set 804 of logical cells 806 when writing the set of data values to the set 804 of logical cells 806.

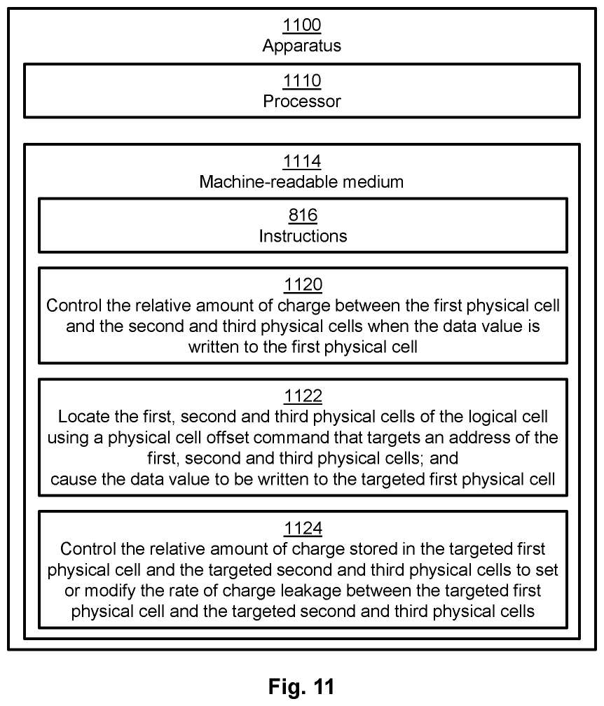

FIG. 11 is a simplified schematic drawing of an example apparatus 1100 for providing an interface to a memory device (e.g., the memory device 402 as depicted by FIG. 4, to which reference is made). In FIG. 11, reference signs for features of the apparatus 1100 that are similar or like corresponding features of the apparatus 1000 are incremented by 100 compared with FIG. 10.

Similar to the apparatus 1000, the apparatus 1100 comprises a processor 1110 and a machine-readable medium 1114. The logical cell 406 of the memory device (not shown but see FIG. 4 for an example) comprises a first physical cell 408a for storing charge indicative of the data value, a second physical cell 408b adjacent to the first physical cell 408a; and a third physical cell 408c adjacent to the first physical cell 408a. Charge stored in the second and third physical cells 408b-c controls the rate of charge leakage between the first physical cell 408a and the second and third physical cells 408b-c.

The machine-readable medium 1114 stores instructions 816 to cause the processor 1110 to implement certain functionality described in relation to the apparatus 800 of FIG. 8.

Further instructions are described below. Certain instructions may be omitted or implemented in a different order to that depicted by FIG. 11. Functionality relating to certain other examples described herein may be implemented by corresponding instructions stored in the machine-readable medium 1114.

In some examples, the machine-readable medium 1114 further stores instructions 1120 to cause the processor 1110 to control the relative amount of charge between the first physical cell 408a and the second and third physical cells 408b-c when the data value is written to the first physical cell 408a.

In some examples, where the request is indicative of the data value to be written to the first physical cell, the machine-readable medium 1114 further stores instructions 1122 to, where the memory operation comprises a data write operation, cause the processor 1110 to locate the first, second and third physical cells 408a-c of the logical cell 406 using a physical cell offset command that targets an address of the first, second and third physical cells 408a-c. The instructions 1122 are further to cause the processor 1110 to cause the data value to be written to the targeted first physical cell 408a. In some examples, the machine-readable medium 1114 further stores instructions 1124 to, where the memory operation comprises a data write operation or a data read operation, cause the processor 1110 to control the relative amount of charge stored in the targeted first physical cell 408a and the targeted second and third physical cells 408b-c to set or modify the rate of charge leakage between the targeted first physical cell 408a and the targeted second and third physical cells 408b-c, where the data value written to the targeted first physical cell 408a is to change in dependence on the set or modified rate of charge leakage. In such examples, the memory operation may change the data degradation rate by changing the relative amount of charge stored in the physical cells 408a-c, for example, such that the data becomes valid sooner than expected, loses validity sooner than expected or otherwise changes the time period over which the data is valid.

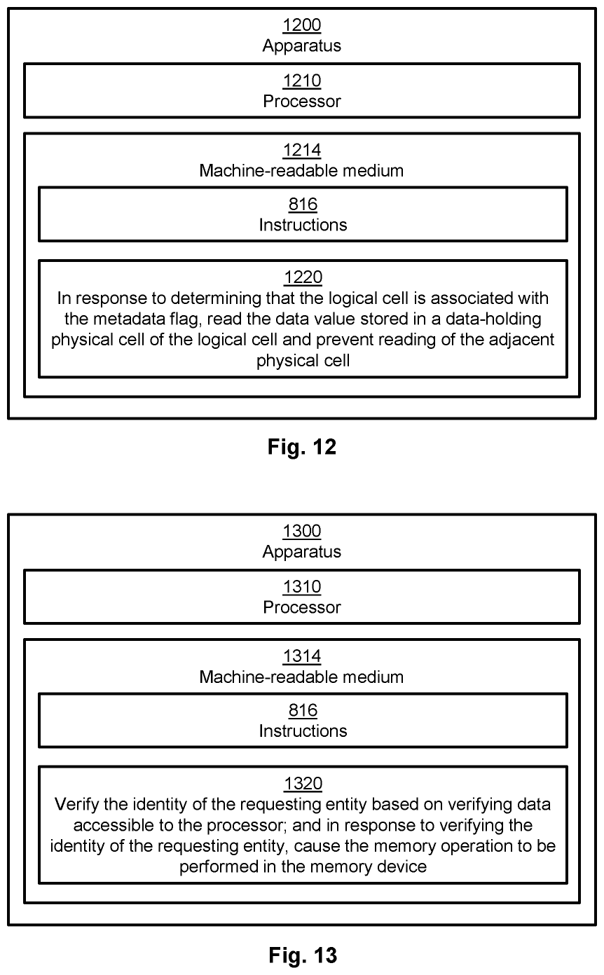

FIG. 12 is a simplified schematic drawing of an example apparatus 1200 for providing an interface to a memory device (e.g., the memory device 802 as depicted by FIG. 8, to which reference is made). In FIG. 12, reference signs for features of the apparatus 1200 that are similar or like corresponding features of the apparatus 800 are incremented by 400 compared with FIG. 8.

The apparatus 1200 comprises a processor 1210 and a machine-readable medium 1214. The machine-readable medium 1214 stores instructions 816 to cause the processor 1210 to implement certain functionality described in relation to the apparatus 800 of FIG. 8.

Further instructions are described below. Certain instructions may be omitted or implemented in a different order to that depicted by FIG. 12. Functionality relating to certain other examples described herein may be implemented by corresponding instructions stored in the machine-readable medium 1214.

In some examples, the logical cell 806 is associated with a metadata flag (e.g., accessible to the processor 1210 for pointing to which namespaces comprise ‘enhanced’ logical cells 806) indicative of the logical cell 806 comprising a data-holding physical cell 808a and an adjacent physical cell 808b for storing charge for controlling the rate of charge leakage.

In some examples, where the memory operation comprises a data read operation, the machine-readable medium 1214 stores instructions 1220 to cause processor 1210 to, in response to determining that the logical cell 806 is associated with the metadata flag, read the data value stored in a data-holding physical cell 808a of the logical cell 806 and prevent reading of the adjacent physical cell 808b.

FIG. 13 is a simplified schematic drawing of an example apparatus 1300 for providing an interface to a memory device (e.g., the memory device 802 as depicted by FIG. 8, to which reference is made). In FIG. 13, reference signs for features of the apparatus 1300 that are similar or like corresponding features of the apparatus 800 are incremented by 500 compared with FIG. 8.

The apparatus 1300 comprises a processor 1310 and a machine-readable medium 1314. The machine-readable medium 1314 stores instructions 816 to cause the processor 1310 to implement certain functionality described in relation to the apparatus 800 of FIG. 8.

Further instructions are described below. Certain instructions may be omitted or implemented in a different order to that depicted by FIG. 13. Functionality relating to certain other examples described herein may be implemented by corresponding instructions stored in the machine-readable medium 1314.

In some examples, where the request comprises an indication of an identity of a requesting entity (e.g., an identify of the computing system 812 itself and/or a user associated with the computing system 812) that generated the request (such as digital signature or password as described above), the machine-readable medium 1314 stores instructions 1320 to cause the processor 1310 to verify the identity of the requesting entity based on ‘verifying data’ (as described above) accessible to the processor 1310. The instructions 1320 further cause the processor 1310 to, in response to verifying the identity of the requesting entity, cause the memory operation to be performed in the memory device 802.

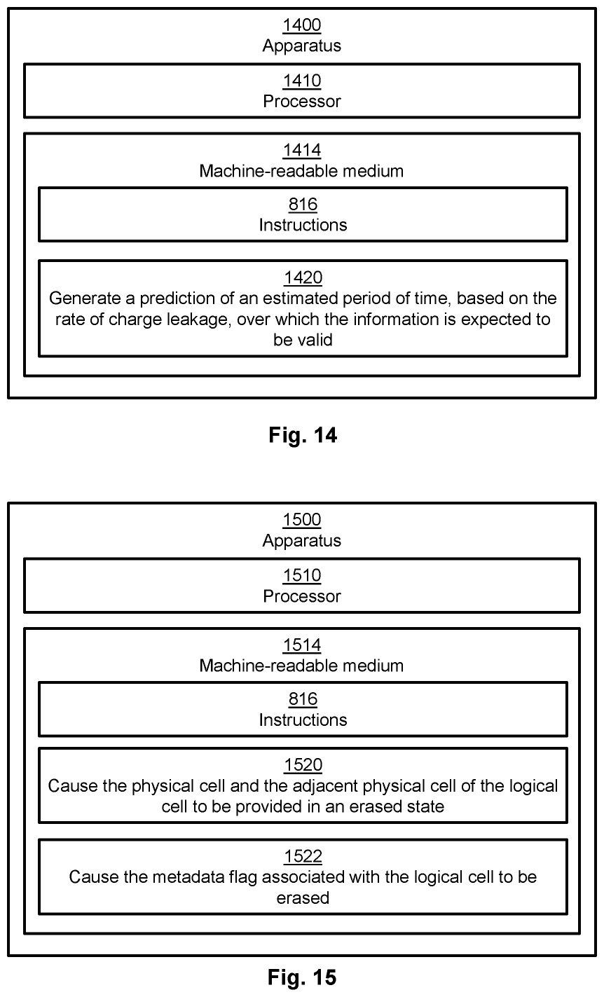

FIG. 14 is a simplified schematic drawing of an example apparatus 1400 for providing an interface to a memory device (e.g., the memory device 802 as depicted by FIG. 8, to which reference is made). In FIG. 14, reference signs for features of the apparatus 1400 that are similar or like corresponding features of the apparatus 800 are incremented by 600 compared with FIG. 8.

The apparatus 1400 comprises a processor 1410 and a machine-readable medium 1414. The machine-readable medium 1414 stores instructions 816 to cause the processor 1410 to implement certain functionality described in relation to the apparatus 800 of FIG. 8.

Further instructions are described below. Certain instructions may be omitted or implemented in a different order to that depicted by FIG. 14. Functionality relating to certain other examples described herein may be implemented by corresponding instructions stored in the machine-readable medium 1414.

In some examples, the request comprises a request for information about validity of information stored in the set 804 of logical cells 806, and the machine-readable medium 1414 stores instructions 1420 to cause the processor 1410 to generate a prediction of an estimated period of time, based on the rate of charge leakage, over which the information is expected to be valid. This may refer to the verification/attestation operation described above where the request may be to generate the prediction and the prediction may be used to attest to the estimated period of time via an indication sent to the apparatus 1400 to the computing system 812.

FIG. 15 is a simplified schematic drawing of an example apparatus 1500 for providing an interface to a memory device (e.g., the memory device 802 as depicted by FIG. 8, to which reference is made). In FIG. 15, reference signs for features of the apparatus 1500 that are similar or like corresponding features of the apparatus 800 are incremented by 700 compared with FIG. 8.

The apparatus 1500 comprises a processor 1510 and a machine-readable medium 1514. The machine-readable medium 1514 stores instructions 816 to cause the processor 1510 to implement certain functionality described in relation to the apparatus 800 of FIG. 8.

Further instructions are described below. Certain instructions may be omitted or implemented in a different order to that depicted by FIG. 15. Functionality relating to certain other examples described herein may be implemented by corresponding instructions stored in the machine-readable medium 1514.

In some examples, where the memory operation comprises a data erase operation to erase the data value stored in the logical cell 806, the machine-readable medium 1514 stores instructions 1520 to cause the processor 1510 to cause the physical cell 808a and the adjacent physical cell 808b of the logical cell 806 to be provided in an erased state.

In some examples, where the logical cell 806 is associated with a metadata flag (e.g., stored in memory accessible to the processor 1510 such as in the memory device 802 or an interface associated with the memory device 802) indicative of the logical cell 806 storing the data value for an estimated period of time based on the rate of charge leakage (and where the instructions to cause the physical cell 808a and the adjacent physical cell 808b of the logical cell 806 to be provided in an erased state), the machine-readable medium 1514 further stores instructions 1522 to cause the processor 1510 to cause the metadata flag associated with the logical cell 806 to be erased.

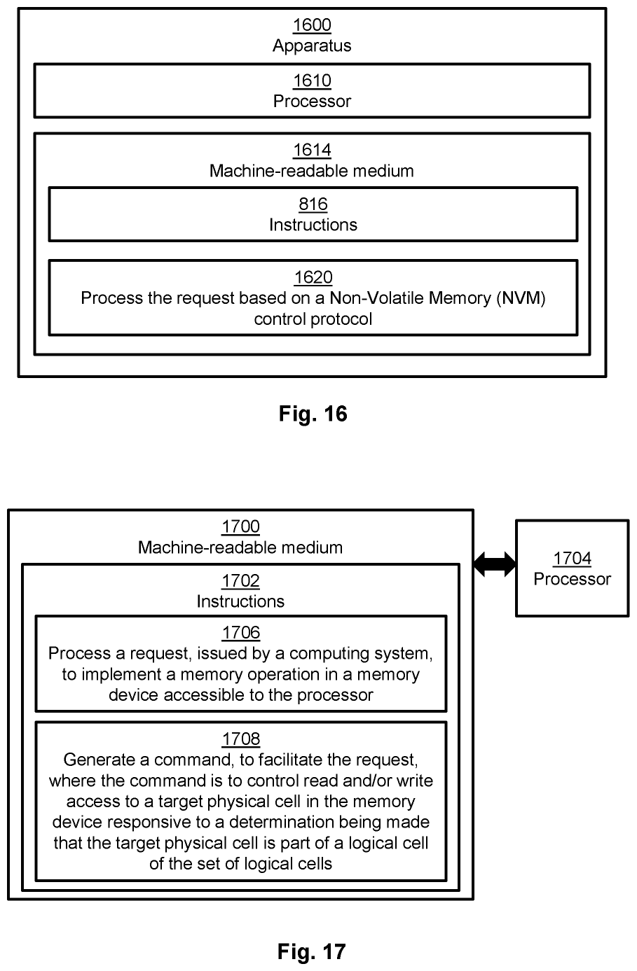

FIG. 16 is a simplified schematic drawing of an example apparatus 1600 for providing an interface to a memory device (e.g., the memory device 802 as depicted by FIG. 8, to which reference is made). In FIG. 16, reference signs for features of the apparatus 1600 that are similar or like corresponding features of the apparatus 800 are incremented by 800 compared with FIG. 8.

The apparatus 1600 comprises a processor 1610 and a machine-readable medium 1614. The machine-readable medium 1614 stores instructions 816 to cause the processor 1610 to implement certain functionality described in relation to the apparatus 800 of FIG. 8.

Further instructions are described below. Certain instructions may be omitted or implemented in a different order to that depicted by FIG. 16. Functionality relating to certain other examples described herein may be implemented by corresponding instructions stored in the machine-readable medium 1614.

In some examples, machine-readable medium stores instructions 1620 to cause the processor 1610 to process the request based on a Non-Volatile Memory (NVM) control protocol such as the NVMe specification (e.g., implemented by an interface according to any example described herein). The NVM/NVMe control protocol specifies an address of a logical cell 806 to be targeted in the set 804 of logical cells 806 to control a memory operation in the targeted logical cell 806 such that a data-holding physical cell 808a of the targeted logical cell 806 is addressable as part of the memory operation and the adjacent physical cell 808b of the targeted cell 806 is addressable for controlling the rate of charge leakage.

FIG. 17 schematically illustrates an example machine-readable medium 1700 for facilitating provision of an interface to a memory device (e.g., the memory device 802 as depicted by FIG. 8, to which reference is made). In FIG. 17, reference signs for features of the machine-readable medium 1700 that are similar or like corresponding features of the apparatus 800 are incremented by 900 compared with FIG. 8.

The machine-readable medium 1700 (e.g., a non-transitory machine-readable medium) stores instructions 1702 which, when executed by a processor 1704, cause the processor 1704 to implement the functionality defined by the following instructions. In this example, the machine-readable medium 1700 is implemented by apparatus (e.g., corresponding to an ‘interface’) such as referred to in various examples described herein.

The instructions 1702 comprise instructions 1706 to cause the processor 1704 to process a request, issued by a computing system 812, to implement a memory operation in a memory device 802 accessible to the processor 1704. The memory device 802 comprises a set 804 of logical cells 806. Each logical cell 806 comprises a physical cell 808a for storing charge indicative of a data value and an adjacent physical cell 808b for storing charge for controlling a lifetime of the stored charge indicative of the data value.

The instructions 1702 comprise further instructions 1708 to cause the processor 1704 to generate a command, to facilitate the request. The command is to control read and/or write access to a target physical cell 808a-b in the memory device 802 responsive to a determination being made that the target physical cell 808a-b is part of a logical cell 806 of the set 804 of logical cells 806.

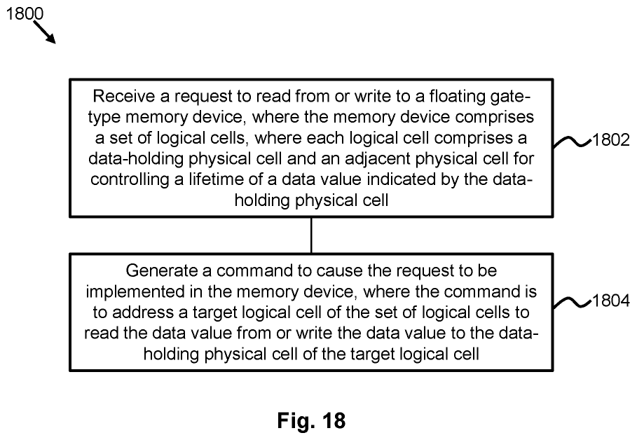

FIG. 18 depicts a flowchart of an example method 1800 of operating an interface. The method 1800 may be a computer-implemented method (e.g., implemented using processing circuitry). In some examples, the method 1800 may be implemented by (e.g., a processor of) the interface as already mentioned and as described in more detail in various examples. In FIG. 18, reference signs for features of the method 1800 that are similar or like corresponding features of the apparatus 800 are incremented by 1000 compared with FIG. 8.

The method 1800 comprises, at block 1802, receiving a request to read from or write to a floating gate-type memory device 802. The memory device 802 comprises a set 804 of logical cells 806. Each logical cell 806 comprises a data-holding physical cell 808a and an adjacent physical cell 808b for controlling a lifetime of a data value indicated by the data-holding physical cell 808a.

The method 1800 further comprises, at block 1804, generating a command to cause the request to be implemented in the memory device 802. The command is to address a target logical cell 806 of the set 804 of logical cells 806 to read the data value from or write the data value to the data-holding physical cell 808a of the target logical cell 806.

Certain features of examples described above in relation to ‘interfacing with memory devices’ may be combined with, replace features of or incorporate features from examples described herein in relation to ‘validity of information stored in memory devices’ and/or ‘encryption of data in memory devices’.

### Encryption of Data in Memory Devices

In some examples, the memory devices described herein may implement a security protocol such as with encryption/decryption on the host side (e.g., the ‘computing system’) and/or on the memory device side. Such a security protocol may make it more difficult for an attacker to tamper with the privacy policies and/or enforcement mechanisms associated with the memory device.

Certain examples described above may not prevent the stored ‘information’ from being accessed in cleartext, by anyone, on any platform, and copying the content (providing the interface permits such access). If a privacy policy is attached to the information, it cannot be assured that this policy is enforced at all times.

The use of the charge leakage effect to control access to information may potentially enforce a privacy policy but this may not be enforced in all circumstances. For example, it may not be possible to prevent the valid information from being copied to another storage device where privacy would not be enforced. Various examples may improve privacy enforcement in case of copying.

In some examples, the information (as represented by the set of data values) may be encrypted with a key that is tied to a given platform. Encryption may reduce the likelihood that the information can be decrypted on any system, thus making it more difficult to decrypt encrypted data that has been copied by linking the memory device to any computer.

In some examples, the information may be encrypted with a secret that is linked to the memory device itself and is prevented from being copied to an external device, for example, a Physical Unclonable Function (PUF). If the encrypted data is copied to another storage device, this data is not decryptable. In other words, an entity needs to have possession of the memory device storing the PUF in order to decrypt the data.

Such examples may make it more difficult for an attacker to copy the data in unencrypted form and/or not comply with privacy policies.

Certain features of examples described above in relation to ‘encryption of data in memory devices’ may be combined with, replace features of or incorporate features from examples described herein in relation to ‘validity of information stored in memory devices’ and/or ‘interfacing with memory devices’.

Further details of various implementations are described below.

Any of the blocks, nodes, instructions or modules described in relation to the figures may be combined with, implement the functionality of or replace any of the blocks, nodes, instructions or modules described in relation to any other of the figures. For example, methods may be implemented as machine-readable media or apparatus, machine-readable media may be implemented as methods or apparatus, and apparatus may be implemented as machine-readable media or methods. Further, any of the functionality described in relation to any one of a method, machine readable medium or apparatus described herein may be implemented in any other one of the method, machine readable medium or apparatus described herein. Any claims written in single dependent form may be re-written, where appropriate, in multiple dependency form since the various examples described herein may be combined with each other.

Examples in the present disclosure can be provided as methods, systems or as a combination of machine-readable instructions and processing circuitry. Such machine-readable instructions may be included on a non-transitory machine (for example, computer) readable storage medium (including but not limited to disc storage, CD-ROM, optical storage, flash storage, etc.) having computer readable program codes therein or thereon.

The present disclosure is described with reference to flow charts and block diagrams of the method, devices and systems according to examples of the present disclosure. Although the flow charts described above show a specific order of execution, the order of execution may differ from that which is depicted. Blocks described in relation to one flow chart may be combined with those of another flow chart. It shall be understood that each block in the flow charts and/or block diagrams, as well as combinations of the blocks in the flow charts and/or block diagrams can be realized by machine readable instructions.

The machine-readable instructions may, for example, be executed by a general-purpose computer, a special purpose computer, an embedded processor or processors of other programmable data processing devices to realize the functions described in the description and diagrams. In particular, a processor or processing circuitry, or a module thereof, may execute the machine-readable instructions. Thus, functional nodes, modules or apparatus of the system and other devices may be implemented by a processor executing machine readable instructions stored in a memory, or a processor operating in accordance with instructions embedded in logic circuitry. The term ‘processor’ is to be interpreted broadly to include a CPU, processing unit, ASIC, logic unit, or programmable gate array etc. The methods and functional modules may all be performed by a single processor or divided amongst several processors.

Such machine-readable instructions may also be stored in a computer readable storage that can guide the computer or other programmable data processing devices to operate in a specific mode.

Such machine readable instructions may also be loaded onto a computer or other programmable data processing devices, so that the computer or other programmable data processing devices perform a series of operations to produce computer-implemented processing, thus the instructions executed on the computer or other programmable devices realize functions specified by block(s) in the flow charts and/or in the block diagrams.

Further, the teachings herein may be implemented in the form of a computer program product, the computer program product being stored in a storage medium and comprising a plurality of instructions for making a computer device implement the methods recited in the examples of the present disclosure.

While the method, apparatus and related aspects have been described with reference to certain examples, various modifications, changes, omissions, and substitutions can be made without departing from the scope of the present disclosure. It is intended, therefore, that the method, apparatus and related aspects be limited by the scope of the following claims and their equivalents. It should be noted that the above-mentioned examples illustrate rather than limit what is described herein, and that many implementations may be designed without departing from the scope of the appended claims. Features described in relation to one example may be combined with features of another example.

The word “comprising” does not exclude the presence of elements other than those listed in a claim, “a” or “an” does not exclude a plurality, and a single processor or other unit may fulfil the functions of several units recited in the claims.

The features of any dependent claim may be combined with the features of any of the independent claims or other dependent claims.

1. An apparatus, comprising:
a memory device comprising a set of logical cells, where a logical cell of the set of logical cells indicates a data value by an amount of charge stored in a physical cell of the logical cell, where charge leakage between the physical cell and an adjacent physical cell of the logical cell is to occur at a rate that at least partially depends on a relative amount of charge stored in the physical cell and the adjacent physical cell, where:
a set of data values indicated by the set of logical cells is to change over time due to the charge leakage; and
the set of data values indicated by the set of logical cells is representative of information that is valid over an estimated period of time, where the estimated period of time is based on the rate of charge leakage.

2. The apparatus of claim 1, where the information comprises at least part of a cryptographic key.

3. The apparatus of claim 1, where the estimated period of time has a start time of when a data write operation is performed to store the information in the set of logical cells and an end time, after which the information becomes at least partially invalid due to at least one data value indicated by the set of logical cells changing due to the charge leakage.

4. The apparatus of claim 1, where the estimated period of time has a start time after a data write operation is performed to store a set of data values in the set of logical cells, where the stored set of data values is to change over time due to the charge leakage before the information becomes valid over the estimated period of time.

5. The apparatus of claim 1, where the estimated period of time has:
an estimated start time after a data write operation is performed to store a set of data values in the set of logical cells, where the stored set of data values is to change over time due to the charge leakage before the information becomes valid over the estimated period of time; and
an estimated end time, after which the information becomes at least partially invalid due to at least one data value indicated by the set of logical cells changing due to further charge leakage.

6. The apparatus of claim 1, where the logical cell comprises:
a first physical cell for storing charge indicative of the data value;
a second physical cell adjacent to the first physical cell; and
a third physical cell adjacent to the first physical cell, where charge stored in the second and third physical cells is to control the rate of charge leakage between the first physical cell and the second and third physical cells, where the set of logical cells have three possible logical states, in which:
in a first logical state:
the charge stored by each first physical cell of the set of logical cells is indicative of a valid data value making up part of the information;
in a second logical state:
the charge stored by each first physical cell of a first subset of the set of logical cells is indicative of a valid data value making up part of the information; and
the charge stored by each first physical cell of a second subset of the set of logical cells is indicative of an invalid data value such that the information is masked by the second subset; and
in a third logical state:
the charge stored by each first physical cell of the set of logical cells is such that the set of logical cells is erased of any information.

7. The apparatus of claim 6, where:
the charge stored by each first physical cell of the set of logical cells when in the first logical state corresponds to a bit value of 0 or 1 and represents a valid data value making up part of the information;
the charge stored by each first physical cell of the set of logical cells when in the second logical state corresponds to a bit value of 0, irrespective of whether the charge stored is indicative of a valid data value or an invalid data value; and
the charge stored by each first physical cell of the set of logical cells when in the third logical state corresponds to a bit value of 1.

8. The apparatus of claim 6, where the set of logical cells is to transition from the second logical state to the first logical state at a start time of the estimated period of time.

9. The apparatus of claim 6, where the set of logical cells is to transition from the first logical state to the third logical state after the estimated period of time has elapsed.

10. The apparatus of claim 6, where the set of logical cells is to:
transition from the second logical state to the first logical state at a start time of the estimated period of time; and
transition from the first logical state to the third logical state at an end time of the estimated period of time.

11. The apparatus of claim 1, where the memory device is a type of floating-gate memory.

12. An apparatus, comprising:
a memory device comprising a set of logical cells, where each logical cell comprises a data-holding first physical cell and a second and third adjacent physical cell for controlling a lifetime of a data value indicated by the first physical cell, where charge stored in the second and third physical cells controls a rate of charge leakage between the first physical cell and the second and third physical cells to control the lifetime of the data value stored in the first physical cell; and
a processor to:
control the amount of charge injected into the second and third physical cells as part of a data write operation to write a set of data values to the set of logical cells; and
define the rate of charge leakage, such that:
the set of data values indicated by the set of logical cells over an estimated period of time is representative of information that is valid over the estimated period of time, where a start time and end time of the estimated period of time is defined by the rate of charge leakage.

13. A method, comprising:
controlling, using processing circuitry, a relative amount of charge stored in adjacent physical cells of a logical cell in a memory device comprising a set of logical cells as part of a memory operation, where:
the amount of charge stored in a data-holding physical cell of the logical cell is indicative of a data value;
the memory operation provides the set of logical cells in an initial logical state and the set of logical cells is transitionable to at least one other logical state after leakage of charge between the adjacent physical cells within the set of logical cells;
the relative amount of charge stored in the adjacent physical cells defines a charge leakage rate between the adjacent physical cells;
the charge leakage rate defines an estimated timing of a transition from the initial logical state to the at least one other logical state;
a set of data values stored by the set of logical cells represents valid information when the set of logical cells is in one of the logical states; and
the set of data values stored by the set of logical cells represents at most partially valid information when the set of logical cells is in another of the logical states.

14. The method of claim 13, where, after transitioning from the logical state where the set of data values stored by the set of logical cells represents valid information to the other logical state where the set of data values stored by the set of logical cells represents at most partially valid information, the method comprises:
retrieving the data value stored by the data-holding physical cell of at least one of the set of logical cells;
accessing an error correction code accessible to the processing circuitry; and
applying, using the processing circuitry, the error correction code to determine whether the retrieved data value is a valid data value making up part of the information; and
in response to determining that the retrieved data value is not a valid data value, indicating that retrieved data value was different prior to the transition.

15. The method of claim 13, where the memory device comprises a first set of logical cells for storing a first portion of the information and a second set of logical cells for storing a second portion of the information, the method comprising:
controlling, using the processing circuitry, the relative amount of charge stored in adjacent physical cells within the first set of logical cells to define a first charge leakage rate; and
controlling, using the processing circuitry, the relative amount of charge stored in adjacent physical cells within the second set of logical cells to define a second charge leakage rate different to the first charge leakage rate such that the estimated timing of the transition is different for the first and second set of logical cells.
